(19) United States
(12) Patent Application Publication
(10) Pub. No.: US 2026/0148940 A1
(43) Pub. Date: May 28, 2026

(54) SEMICONDUCTOR PROCESSING SYSTEMS INCLUDING PROCESS MODULES AND GAS DELIVERY ASSEMBLIES CONFIGURED FOR PERFORMING CONCURRENT EPITAXIAL DEPOSITION OF MATERIAL LAYERS

(71) Applicant: ASM IP Holding B.V., Almere (NL)

(72) Inventors: Chenhui Yan, Chandler, AZ (US); Yanfu Lu, Phoenix, AZ (US); Omar Elleuch, Litchfield Park, AZ (US); Alexandros Demos, Scottsdale, AZ (US)

(21) Appl. No.: 19/398,321

(22) Filed: Nov. 24, 2025

Related U.S. Application Data
(60) Provisional application No. 63/726,029, filed on Nov. 27, 2024.

(51) Int. Cl. H01J 37/32; C23C 16/44; C23C 16/455; C23C 16/52; C30B 25/08; C30B 25/14; C30B 25/16; H01L 21/67

(52) U.S. Cl. CPC H01J 37/32449; C23C 16/4411; C23C 16/45561; C23C 16/52; C30B 25/08; C30B 25/14; C30B 25/165; H01J 2237/332; H10P 72/0454

(57) ABSTRACT

A semiconductor processing system configured for performing concurrent epitaxial deposition of material layers is disclosed. The system includes a process module with a first and second chamber body, each having upper and lower walls extending between injection and exhaust chamber flanges. The gas delivery system comprises sources of gas and additional gas, with gas conduits fluidly coupled to the chamber bodies. A gas manifold with input and output conduits directs the additional gas to the chamber bodies, controlled by flow controllers. The chamber bodies are laterally separated and positioned adjacent to each other on either side of a central plane, facilitating efficient concurrent deposition processes.

### CROSS-REFERENCE TO RELATED APPLICATIONS

This application is a nonprovisional of, and claims priority to and the benefit of, U.S. Provisional Ser. No. 63/726,029 , filed Nov. 27, 2024 and entitled “SEMICONDUCTOR PROCESSING SYSTEMS INCLUDING PROCESS MODULES AND GAS DELIVERY ASSEMBLIES CONFIGURED FOR PERFORMING CONCURRENT EPITAXIAL DEPOSITION OF MATERIAL LAYERS,” which is hereby incorporated by reference herein.

### FIELD

The present disclosure relates generally to the field of systems and apparatus employed in the manufacture of semiconductor devices and integrated circuits. More particularly, the present disclosure relates to process modules configured for performing concurrent epitaxial deposition of material layers, semiconductor processing systems comprising such process modules, as well as methods of performing concurrent epitaxial deposition of material layers.

### BACKGROUND

Semiconductor processing methods, such as chemical vapor deposition (CVD) and plasma-enhanced chemical vapor deposition (PECVD), are common processes for forming thin layers of materials on substrates, such as silicon wafers. In a CVD process, for example, gaseous molecules of the material to be deposited are supplied to substrates to form a thin layer of that material on the substrates by chemical reactions. Such deposited thin layers may be polycrystalline, amorphous, or epitaxial.

During a typical CVD process, one or more substrates are placed on a substrate support (e.g., a susceptor) inside a chamber within the reactor. Both the substrate and the substrate support are typically heated to a desired temperature. In a typical substrate deposition step, reactant gases are passed over the heated substrate causing deposition of a thin layer of a desired material on the substrate surface. If the deposited layer has the same crystallographic structure as an underlying silicon surface, the deposited layer is called an epitaxial layer (or a monocrystalline). Through subsequent processes, these layers may be used to form a semiconductor device, such as an integrated circuit.

Typically, CVD processes are conducted at elevated temperatures to accelerate the chemical reaction and to produce high quality films, with some of these processes, such as epitaxial silicon deposition, being conducted at extremely high temperatures (e.g., greater than 1800° C.). However, as device structures become ever more complex with increasing numbers of deposited layers the time required to deposit such layers is increasing. Such an increase in deposition time can impact substrate through-put and reduce tool efficiency. Therefore, there is a desire for chemical vapor deposition systems with increased throughput, and flexibility.

Any discussion, including discussion of problems and solutions set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In one aspect, a semiconductor processing system configured for performing concurrent epitaxial deposition of material layers in a process module includes a first chamber body and a second chamber body, the semiconductor processing system includes a gas delivery system includes a first source of a gas, a second source of the gas, and a source of an additional gas, a first gas conduit fluidly coupled to the first source of a gas and to the first chamber body, a second gas conduit fluidly coupled to the second source of the gas and to the second chamber body, and a gas manifold includes an input conduit coupled to the source of the additional gas, a first output conduit fluidly coupled to the input conduit and the first chamber body, and a second output conduit fluidly coupled to the input conduit and the second chamber body. The semiconductor processing system configured also includes a first flow controller operably coupled to the first output conduit and configured for controlling the flow of the additional gas to the first chamber body. The semiconductor processing system configured also includes a second flow controller operably coupled to the second output conduit and configured for controlling the flow of the additional gas to the second chamber body. The semiconductor processing system configured also includes where the first chamber body and the second chamber body both have an upper wall and a lower wall, the upper wall extending longitudinally between an injection chamber flange and a longitudinally opposite exhaust chamber flange, the lower wall being below and parallel relative to the upper wall, and where the first chamber body and the second chamber body are laterally separated by a lateral separation distance and positioned adjacent to one another on either side of a central plane. The semiconductor processing system may also include further includes a first gas distribution assembly fluidically coupled downstream to gas delivery system and fluidically coupled upstream to the first chamber body, and a second gas distribution assembly fluidically coupled downstream to the gas delivery system and fluidically coupled upstream to the second chamber body. The semiconductor processing system may also include where the first chamber body includes a first ceramic weldment having a first chamber exterior includes a plurality of first external ribs extending laterally about the first chamber exterior, and a first chamber interior enclosing a first process volume and where the second chamber body includes a second ceramic weldment having a second chamber exterior includes a plurality of second external ribs extending laterally about the second chamber exterior, and a second chamber interior enclosing a second process volume. Other technical features may be readily apparent to one skilled in the art from the following figures, descriptions, and claims. The semiconductor processing system may also include further includes a first injection flange assembly mechanically coupled to the first chamber body and fluidically coupled to the first gas distribution assembly, and a second injection flange assembly mechanically coupled to the second chamber body and fluidically coupled to the second gas distribution assembly. The semiconductor processing system may also include where the gas delivery system further includes a precursor source system including one or more precursor gases and an etchant source system including one or more etchant gases. The semiconductor processing system may also include where the first gas distribution assembly and the second gas distribution assembly both comprise a plurality of precursor gas lines fluidly coupled to the precursor source system, and a plurality of etchant gas lines fluidly coupled to the etchant source system. The semiconductor processing system may also include where the first source of the gas and the second source of the gas comprise a precursor gas, the precursor gas includes a chemical compound including an elemental component that is an elemental component of the chemical formula of the epitaxially deposited material layer. The semiconductor processing system may also include where the precursor gas includes at least one of a silicon precursor, a germanium precursor, and a dopant gas. The semiconductor processing system may also include where the additional gas includes an etchant gas, or an inert gas includes a chemical compound including an elemental component that is not an elemental component of the chemical formula of the epitaxially deposited material layer. The semiconductor processing system may also include where the additional gas is an inert gas. The semiconductor processing system may also include where the first source of the gas and the second source of the gas comprise an etchant gas, the etchant gas includes a chemical compound including an elemental component that is not an elemental component of the chemical formula of the epitaxially deposited material layer. The semiconductor processing system may also include where the etchant gas includes a halide etchant. The semiconductor processing system may also include where the upper wall includes an upper wall plate portion and an upper wall rib portion defining an upper wall unwelded ribbed region formed from a first singular quartz workpiece using a subtractive manufacturing technique thereby forming an upper portion of the plurality of first external ribs and the plurality of second external ribs. The semiconductor processing system may also include where the lower wall includes a lower wall plate portion and a lower wall rib portion defining a lower wall unwelded ribbed region formed from a second singular quartz workpiece using a subtractive manufacturing technique and forming a lower portion of the plurality of first external ribs and the plurality of second external ribs. The semiconductor processing system may also include further includes a longitudinal coolant channel disposed between the first chamber body and the second chamber body, the longitudinal coolant channel being defined at least in part by the lateral separation distance between the first chamber body and the second chamber body. The semiconductor processing system may also include further includes a cooling system coupled to the longitudinal coolant channel, the cooling system configured to provide a coolant fluid flow through the longitudinal coolant channel thereby at least partially providing temperature isolation between the first process volume and the second process volume. The semiconductor processing system may also include where the longitudinal coolant channel further includes a first longitudinal septum member coupled to the first chamber body and a second longitudinal septum member coupled to the second chamber body; where the first longitudinal septum member and the second longitudinal septum member are laterally positioned adjacent to one another on either side of the central plane, and where the first longitudinal septum member and the second longitudinal septum member form a heat exchanger assembly configured to receive the coolant fluid flow from the cooling system. The semiconductor processing system may also include where the semiconductor processing system includes a cluster-type platform includes one or more process modules. Other technical features may be readily apparent to one skilled in the art from the following figures, descriptions, and claims.

In accordance with various embodiments of the disclosure, a semiconductor processing system configured for performing concurrent epitaxial deposition of material layers in a process module including a first chamber body and a second chamber body is provided, the system comprising: a gas delivery system including a first source of a gas and a source of an additional gas; a first gas conduit fluidly coupled to the first source of a gas and to the first chamber body; and a gas manifold including an input conduit coupled to the source of the additional gas, a first output conduit fluidly coupled to the input conduit and the first chamber body, and a second output conduit fluidly coupled to the input conduit and the second chamber body; wherein the source of the additional gas includes two or more gas sources and a mixing manifold; wherein the two or more gas sources of the source of the additional gas are coupled to gas inputs of the mixing manifold; wherein the mixing manifold is configured for mixing incoming gases and includes a single gas output coupled to the input conduit; and wherein the first source of a gas is configured to contain and supply a single gas.

In accordance with various further embodiments of the disclosure, a semiconductor processing system configured for performing concurrent epitaxial deposition of material layers in a process module including a first chamber body and a second chamber body is provided, the system comprising a gas delivery system including a precursor source system including a first precursor source and a first additional source, and an etchant source system including a first etchant source and a second additional source; a precursor input conduit fluidly coupled to the first precursor source and to the first chamber body; an etchant input conduit fluidly coupled to the first etchant source and to the first chamber body; and a first manifold coupling the first additional source to the first chamber body and to the second chamber body; a second manifold coupling the second additional source to the first chamber body and to the second chamber body; wherein the first additional source includes two or more precursor gas sources and a first mixing manifold; wherein the two or more precursor gas sources of the first additional source are coupled to gas inputs of the first mixing manifold; wherein the first mixing manifold is configured for mixing incoming gases and includes a single gas output coupled to the first manifold; wherein the first precursor source is configured to contain and supply a single gas, wherein the second additional source includes two or more etchant gas sources and a second mixing manifold; wherein the two or more etchant gas sources of the second additional source are coupled to gas inputs of the second mixing manifold; wherein the second mixing manifold is configured for mixing incoming gases and includes a single gas output coupled to the second manifold; and wherein the first etchant source is configured to contain and supply a single gas.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 is a schematic view of a semiconductor processing system including a process module including two chamber bodies in accordance with one or more embodiments.

FIG. 2 illustrates a semiconductor processing system in a cluster configuration having a process module including two chamber bodies in accordance with one or more embodiments.

FIG. 3 illustrates a plan view schematic of a process module including two chamber bodies in accordance with one embodiment or more embodiments.

FIG. 4 illustrates a cut-away sectional schematic of a process module including two chamber bodies in accordance with one embodiment or more embodiments

FIG. 5 illustrates an additional cut-away sectional view of a process module including two chamber bodies in accordance with one or more embodiments.

FIG. 6 illustrates a view of the first and second chamber bodies in accordance with one embodiment.

FIG. 7 is an exploded perspective view of a chamber body comprising a ceramic weldment in accordance with one or more embodiments.

FIG. 8 illustrates a schematic view of a portion of semiconductor processing system including a gas delivery system in accordance with one or more embodiments.

FIG. 9 illustrates an additional schematic view of a portion of semiconductor processing system including a gas delivery system in accordance with one or more embodiments.

FIG. 10 illustrates a portion of a gas delivery system including a precursor source system and an etchant source system in accordance with one or more embodiments.

FIG. 11 illustrates a plan view schematic of a portion of a process module including an exhaust assembly in accordance with one or more embodiments.

FIG. 12 illustrates a schematic view of an exhaust assembly in accordance with one or more embodiments.

FIG. 13 illustrates an exploded view of elements making up a portion of an exhaust assembly in accordance with one or more embodiments.

FIG. 14 illustrates an additional exploded view of elements making up a portion of an exhaust assembly in accordance with one or more embodiments.

FIG. 15 illustrates an exhaust flange in accordance with one or more embodiments.

FIG. 16 illustrates a view of a process module including lift mechanisms for raising and lower lamp housings.

FIG. 17 illustrates an additional view of a process module including lift mechanisms for raising and lower lamp housings.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride, and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

The terms “precursor” and/or precursor gases may refer to a gas or combination of gasses that participate in a chemical reaction that produces another compound. For example, precursor gasses may be used to grow an epitaxial layer comprising silicon germanium. Precursor gasses may include a deposition gas or gases, a dopant gas or gases, or a combination of a deposition gas or gases and a dopant gas or gases. The precursor gases may include a silicon precursor such as a high-order silicon precursor. The silicon precursor may further include silane (SiH₄) or chlorosilane (SiCl₄). In some examples, the high-order silicon precursor may have one silicon atom per molecules, such as silane. The high-order silicon precursor may have two or more silicon atoms per molecules, such as disilane. In some examples, the high-order silicon precursors may have three or more silicon atoms. The high-order silicon precursors may include a non-halogenated high-order silicon precursor, such as trisilane and tetrasilane. The high-order silicon precursor may include a halogenated high-order silicon precursor, for example, a high-order chlorine-containing precursors, such as chlorodisilane, dichlorosilane, trichlorosilane, and tetrachloridesilane. The precursor gases may include a high-order germanium-containing material layer precursor, such as germane, digermane, trigermane, their chloride derivatives and mixtures thereof. The precursor gases may include a P-dopant high order precursor such as diborane (B₂H₆). The precursor gases may also include an N-dopant high order precursor such as phosphine (PH₃) and arsine (AsH₃). The precursor gases may include carbon-containing precursors, such as methylsilane (CH₃SiH₃) and Germylmethane ((GeH3)4C), which may help mitigate strain within epitaxial silicon-containing layers, such as SiGeC, for example. In various examples, the incorporation of carbon through such precursors may enable lattice strain compensation, improving the structural integrity and performance of the epitaxial layer in certain semiconductor applications.

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors/reactants (as well as optional additional process gases), which react and/or decompose on a substrate surface to produce a desired deposition.

As used herein the term “monolithic” can refer to various structural components which are integrated into a one-piece unit without readily discernible seams and without openings to accommodate intersecting structures.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure; it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

Various embodiments of the present disclosure relate to process modules including first and second chamber bodies. The process modules are configured for concurrent epitaxial deposition of material layers within the first and second chamber bodies. Semiconductor processing systems including such process modules, as well epitaxial deposition methods for forming epitaxial material layers employing the process modules are also disclosed.

Commonly employed semiconductor processing systems can have a limited throughput of substrates through the system for certain deposition techniques. The limited throughput of substrates through the semiconductor processing systems can be due a number of factors including, but not limited to, the number of substrate supports per unit area occupied by the semiconductor processing system (e.g., in a cluster-type platform). The limitation of number of substrate supports per unit area in semiconductor processing system can have a particular impact on substrate throughput when deposition processes are performed for extended time periods (e.g., beyond 60 minutes or more).

Certain semiconductor processing systems, such as atomic layer deposition (ALD) systems for example, have looked to improve substrate throughput through the use of process modules including 2 or more metal chambers, each including showerheads type gas injection assemblies. However, process modules including multiple metal chambers may not be utilized or directly adapted for epitaxial deposition processes performed at high deposition temperatures. In such high temperature processes a reaction chamber formed from a quartz assembly, which is transparent to heating lamps disposed above and/or below the quartz assembly, may be utilized.

According to various embodiments of the present disclosure, process modules which include two quartz assemblies are provided within a common housing. Such process modules (referred to herein as dual chamber process module) can increase the number of substrate supports per unit area for high-temperature epitaxial deposition process and therefore increase the throughput of substrate through semiconductor processing system (e.g., cluster-type platforms) including such dual chamber process modules.

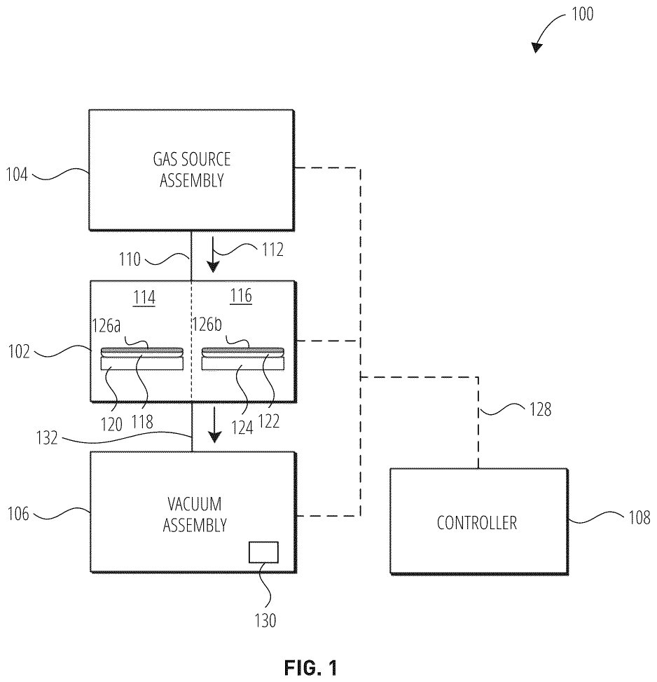

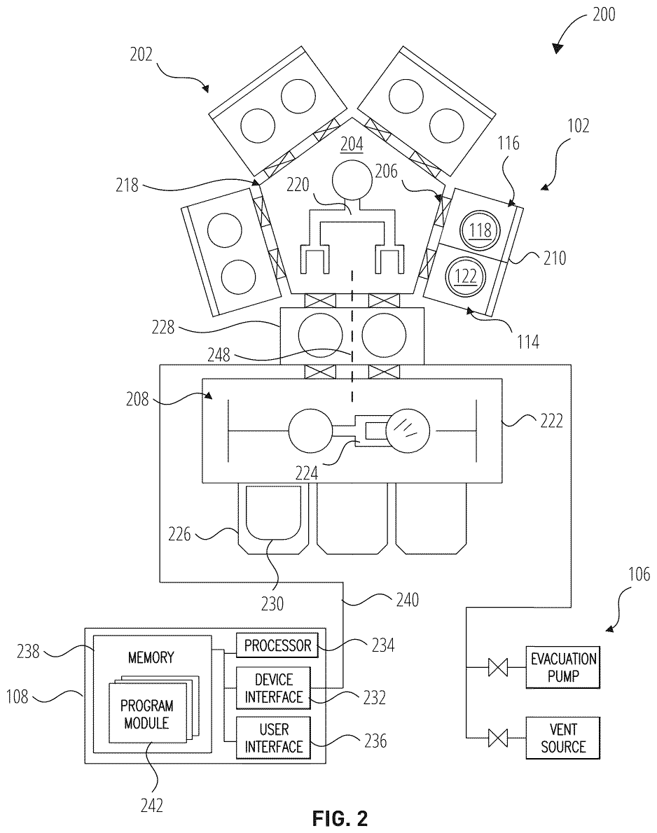

For purposes of explanation and illustration, and not limitation, exemplary semiconductor processing systems including a dual chamber process module are illustrated in FIG. 1 and FIG. 2. The systems and methods of the present disclosure may be used for epitaxial deposit of material layers, such as epitaxial silicon-containing layers, with increased throughput and efficiency by employing dual chamber process modules configured to perform parallel epitaxial CVD processes. As will be appreciated by those of skill in the art in view of the present disclosure, semiconductor processing systems (including dual chamber process module) configured for other material layer deposition operations (e.g., atomic layer deposition, plasma-enhanced deposition, and the like) as well as semiconductor processing systems configured for processing operations other than epitaxial material layer deposition can also benefit from the present disclosure.

FIG. 1 illustrates a schematic view of a semiconductor processing system 100 including a process module comprising a process module 102. Semiconductor processing system 100 further comprises a gas source assembly 104, a vacuum assembly 106, and a controller 108. The gas source assembly 104 is connected to the process module 102 by a precursor supply conduit 110 and is configured to provide a flow of a process gas 112 to the process module 102.

The process module 102 can comprise two independent chamber arrangements, the first chamber arrangement 114 and the second chamber arrangement 116. The first chamber arrangement 114 and the second chamber arrangement 116 can comprise isolated and discrete chamber bodies having independent and isolated interior process volumes in terms of at least, gas communication, temperature control, and vacuum levels therein, as described in detail below. The process module 102 can be configured to expose a first substrate 118, supported on a first substrate support 120, to the process gas 112. The process module 102 can also be configured to independently expose the second substrate 122, supported on the second substrate support 124, to the process gas 112. The gas source assembly 104 can be configured to independently control the flow parameters of the process gas 112 over the first substrate 118 and the second substrate 122. In certain examples, the first substrate 118 and the second substrate 122 are exposed to the process gas 112 under environmental conditions (e.g., temperature, pressure, and the like) selected to cause epitaxial material layers 126a and 126b to be independently deposited onto the first substrate 118 and the second substrate 122.

In some embodiments, the process gas 112 can be supplied to the process module 102 by the gas source assembly 104 and can include one or more silicon-containing precursors. Examples of suitable silicon-containing precursors include non-halogenated silicon-containing material layer precursors, such as silane (SiH₄) and disilane (Si₂H₆), and halogenated silicon-containing material layer precursors, such as dichlorosilane (H₂SiCl₂) and trichlorosilane (HCl₃Si). In accordance with certain examples, the process gas 112 may include an alloying constituent, such as germanium-containing material layer precursor such as germane (GeH₄), a gallium-containing material layer precursor such as triethylgallium Ga(C₂H₅)₃, or an indium-containing material layer precursor such as trimethylindium ((CH₃)₃In). It is contemplated that, in certain examples, the process gas 112 may include one or more dopant-containing material layer precursor. Examples of suitable dopant-containing material layer precursors include p-type dopants like boron (B) and arsenic (As) as well as n-type dopants such as phosphorous (P) and antimony (Sb). It is contemplated that, in accordance with certain examples, the process gas 112 may be co-flowed with a diluent/carrier gas such as hydrogen (H₂) gas or nitrogen (N₂) gas and/or with an etchant, such as hydrochloric (HCl) acid or chlorine (Cl₂) gas.

The vacuum assembly 106 is connected to the process module 102 by an exhaust conduit 132, which is fluidly coupled to an external environment outside of the semiconductor processing system 100 (e.g., through a vacuum pump 130 and/or an abatement device, such as a scrubber, for example). The vacuum assembly 106 (along with a process module exhaust assembly) is configured to independently communicate a flow of residual precursor/reactant and/or any reaction byproducts to the external environment from the first chamber arrangement 114 and the second chamber arrangement 116.

It is contemplated that the controller 108 may be operably connected to one or more of the gas source assembly 104, the process module 102, and the vacuum assembly 106 to control deposition of the material layers (e.g., 126a and 126b) onto the substrates 118 and 122. In this respect the controller 108 may be connected to one or more of the gas source assembly 104, the process module 102, and the vacuum assembly 106 by a wired or wireless link 128 to control at least the temperature of the substrates (118, 122), the pressure within the first chamber arrangement 114 and the second chamber arrangement 116, and the flow of the process gas 112 to the first chamber arrangement 114 and the second chamber arrangement 116. Temperature of the substrates (118, 122) may be controlled, for example, using heater elements and/or temperature sensors included in the process module 102 and operatively associated and/or in communication with the controller 108. Pressure within the first chamber arrangement 114 and the second chamber arrangement 116 may be controlled using the vacuum pump 130 in fluid communication with process module 102 by means of exhaust conduit 132.

FIG. 2 illustrates a further exemplary semiconductor processing system 200. Semiconductor processing system 200 comprises a cluster-type platform 202 comprising two or process modules including at least one process module 102 in accordance with one or more embodiments.

In more detail, the semiconductor processing system 200 includes the exemplary process module 102, a back-end transfer module 204, and a gate valve assembly 206. The process module 102 is coupled to the back-end transfer module 204 by the gate valve assembly 206. The semiconductor processing system 200 also includes an equipment front-end module 208, a controller 108, and a vacuum assembly 106.

In the illustrated example of FIG. 2, the semiconductor processing system 200 includes four (4) process modules, wherein one or more of the process modules includes a dual chamber process module. In certain examples the process module 102 comprises a first chamber arrangement 114 including a first chamber body (not illustrated) and a second chamber arrangement 116 including a second chamber body (not illustrated). First and second chamber bodies are described in detail below. Each chamber arrangement 114 and 116 of the process module 102 includes heaters configured to independently heat a first substrate 118 and a second substrate 122, as described in detail below. In certain examples the first chamber arrangement 114 and the second chamber arrangement 116 can be configured to perform parallel deposition process. In some embodiments, deposition processes may be performed concurrently within the first chamber arrangement 114 and the second chamber arrangement 116. In some embodiments, deposition processes may be performed simultaneously within the first chamber arrangement 114 and the second chamber arrangement 116.

In other examples, the cluster-type platform 202 may include, in additional to one or more dual chamber process module, one or more single chamber process modules, and/or one or more quad chamber module having four (4) chamber arrangements. For example, each process module can be configured to deposit epitaxial material layers. For example, process module 102 of FIG. 2 can be configured to deposit an epitaxial layer onto a first substrate 118 and a second substrate 122 using chemical vapor deposition (CVD) techniques. In certain examples the first chamber arrangement 114 and the second chamber arrangement 116 can comprise isolated and discrete chambers in terms of gas communication there between. The first chamber arrangement 114 and the second chamber arrangement 116 can be configured to perform parallel deposition process. In some embodiments, deposition processes may be performed concurrently within the first chamber arrangement 114 and the second chamber arrangement 116. In some embodiments, deposition processes may be performed simultaneously within the first chamber arrangement 114 and the second chamber arrangement 116.

A process gas source 210 is fluidly coupled to the first chamber arrangement 114 and the second chamber arrangement 116 (e.g., via a gas source assembly 104) and is configured to independently provide a process gas to the chamber arrangements and their associated chamber bodies. The gate valve assembly 206 couples the process module 102 to the back-end transfer module 204 and is configured to provide selective communication between the process module 102 and the back-end transfer module 204. In this respect it is contemplated that the gate valve assembly 206 be configured to permit transfer of the substrates (e.g., 118 and 122) between the back-end transfer module 204 and the process module 102 before and after deposition of an epitaxial material layer onto the substrates.

In accordance with certain examples, the gate valve assembly 206 may include a first process module gate valve and the process module 102 may include a second process module gate valve also coupling the process module 102 to the back-end transfer module 204. It is contemplated that, in certain examples, the process gas source 210 may include a reactant or a precursor suitable for deposition of a material layer, such as using a CVD deposition technique (or ALD, and/or etch processes, and the like). It is also contemplated that, in accordance with certain examples, one or more process modules of semiconductor processing system 200 can include a plasma unit configured to provide a reactant to the substrates as a plasma suitable. In this respect, one or more of the process modules of semiconductor processing system 200 can be configured to deposit a material layer onto the substrates using a PEALD or a PECVD technique by way of example.

The back-end transfer module 204 includes a back-end chamber body 218 and a back-end substrate transfer robot 220. The back-end chamber body 218 is arranged along a transfer axis 248. It is contemplated that the back-end substrate transfer robot 220 be arranged within an interior of the back-end chamber body 218 and supported within the back-end chamber body 218 for movement relative to the back-end chamber body 218 for transfer of substrates, e.g., the first substrate 118 and the second substrate 122, between the gate valve assembly 206 and the process module 102. In certain examples, the back-end chamber body 218 may have a polygonal shape. In this respect the back-end chamber body 218 may have five sides, fewer than five sides (e.g., a rectangular or square shape), or more than five sides (e.g., a hexagonal shape), and may have the shape of a regular polygon or an irregular polygon.

The equipment front-end module 208 is coupled to the load lock arrangement 228 and includes an enclosure 222, a front-end substrate transfer robot 224, and one or more load port 226. The enclosure 222 houses the front-end substrate transfer robot 224. The front-end substrate transfer robot 224 is within the enclosure 222 for movement relative to the enclosure 222 for transfer of substrates between the one or more load port 226 and the load lock arrangement 228. The one or more load ports 226 are connected to the enclosure 222 and is configured to seat there a pod 230 housing one or more substrates prior to and subsequent to deposition of material layers, onto the substrates. In certain examples, the pod 230 may include a standard mechanical interface pod. In accordance with certain examples, the pod 230 may include a front-opening unified pod. Although shown and described herein as having three (3) load ports it is to be understood and appreciated that equipment front-end module 208 may include fewer or additional load ports and remain within the scope of the present disclosure.

The controller 108 is operably connected to the semiconductor processing system 200 and includes a device interface 232, a processor 234, a user interface 236, and a memory 238. The device interface 232 couples the processor 234 to the semiconductor processing system 200, for example, through (or over) a wired or wireless link 240. The processor 234 is operably connected to the user interface 236 and is disposed in communication with the memory 238. The memory 238 includes a non-transitory machine-readable medium having a plurality of program modules 242 recorded thereon containing instructions that, when read by the processor 234, cause the processor to execute certain operations. Among the operations are operations of a material layer deposition method, as described below.

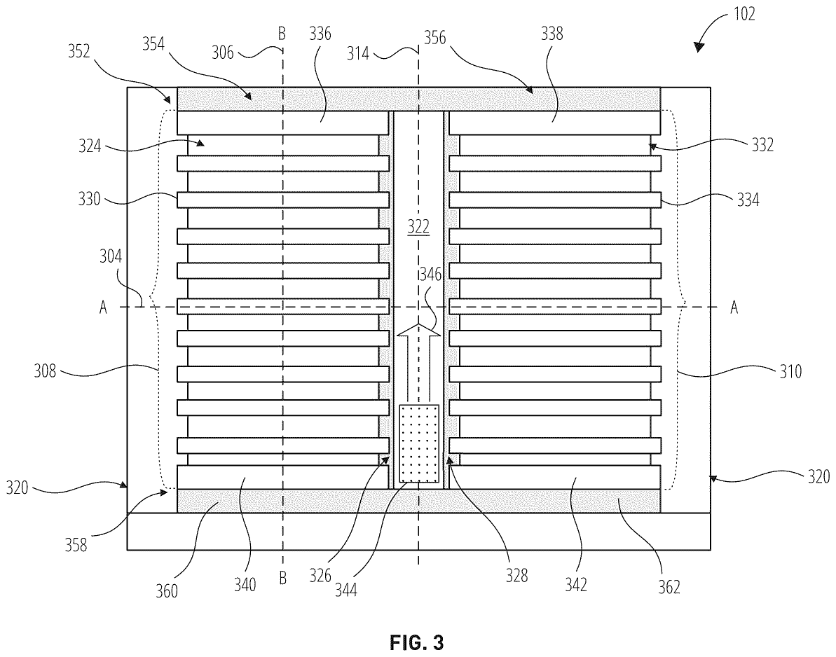

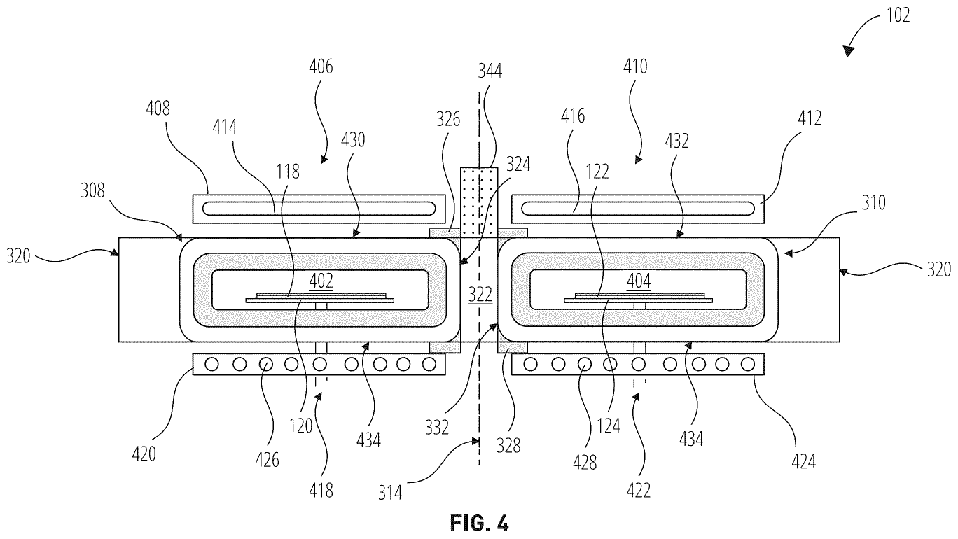

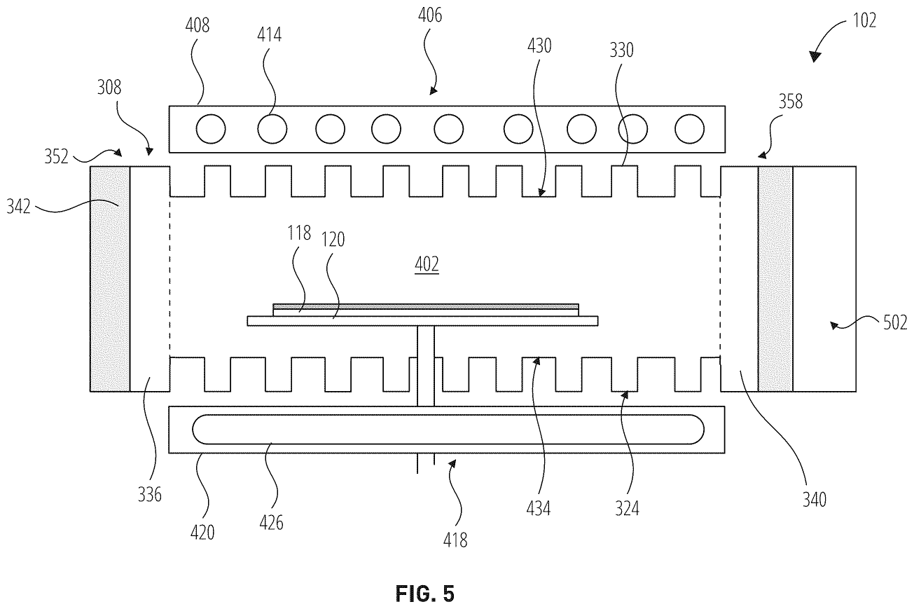

As previously described, the semiconductor processing systems 100 and 200 (FIG. 1 and FIG. 2 respectively) include one or more dual chamber process modules comprising independently controllable first and second chamber arrangements, each chamber arrangement including an associated chamber body, i.e., a first chamber body and a second chamber body. Exemplary dual chamber process modules of the disclosure are illustrated and described in greater detail with reference to FIG. 3-F IG. 7. For example, FIG. 3 illustrates a plan view schematic of a dual chamber process module, FIG. 4 illustrates a cut-away sectional view of the dual chamber process module through the A-A plane 304 (as illustrated in FIG. 3), and FIG. 5 illustrates a cut-away sectional view through the B-B plane 306 (as illustrated in FIG. 3).

In various embodiments a process module 102 is disclosed. The process module 102 (FIG. 3 and FIG. 4) includes a first chamber body 308 and a second chamber body 310 and can be referred to as a dual chamber process module. In some embodiments, the process module 102 can be configured for performing epitaxial deposition of materials layers. In some examples the process module 102 can be configured for performing epitaxial deposition of silicon-containing layers. In certain examples the process module 102 can be configured for performing dual epitaxial deposition of silicon-containing layers within the first chamber body 308 and the second chamber body, either concurrently or simultaneously, thereby increasing the throughput a semiconductor processing system (e.g., 100 or 200) comprising the dual chamber process module 302.

As illustrated in FIG. 3, FIG. 4, and FIG. 5 the process module 102 includes a common chamber housing 312. The common chamber housing 312 has a central plane 314 that bisects the common chamber housing 312. In some embodiments, the common chamber housing 312 can comprise a sleeve housing including one or more housing side walls 320 which allow unobstructed transmission of radiation from one or more heater arrays, as described below.

In various embodiments the first chamber body 308 and the second chamber body 310 are disposed in a common chamber housing 312. In certain examples the first chamber body 308 is positioned in the common chamber housing 312 on a first side (e.g., the left side) of the central plane 314 and the second chamber body 310 is positioned within the common chamber housing 312 on a second side (e.g., the right side) of the central plane 314 (FIG. 3 and FIG. 4). In certain examples the first chamber body 308 and the second chamber body 310 are mirror images of one another about the central plane 314. In such examples, the first chamber body 308 and the second chamber body 310 are laterally positioned adjacent to one another on either side of the central plane 314.

In various embodiments, the first chamber body 308 includes a chamber interior comprising a first process volume 402 and the second chamber body 310 includes a chamber interior comprising a second process volume 404, as illustrated in FIG. 4. The first process volume 402 encompasses the first substrate 118 supported on the first substrate support 120 and the second process volume encompasses the second substrate 122 supported on the second substrate support 124. In various embodiments, the first process volume 402 and the second process volume 404 can be independently controlled (e.g., in terms of temperature, process, and incoming gas flow, for example) to enable independent deposition processes to be performed concurrently upon the first substrate 118 and the second substrate 122. For example, at least the temperature, the incoming flow of process gas, and the pressure within the first process volume 402 and the second process volume 404 may be independently controlled to enable autonomous deposition processes to be performed concurrently within the first and second chamber bodies.

Independent temperature control of the first process volume 402 and the second process volume 404 may be realized by a number of aspects of the present disclosure. In one aspect, independent temperature control between the first process volume 402 and second process volume 404 can be realized at least in part by utilizing independent heater arrays for the first chamber body 308 and the second chamber body 310.

In more detail, FIG. 4 and FIG. 5 illustrate aspects of independent heater arrays for the first chamber body 308 and the second chamber body 310 which in turn allows, at least in part, independent temperature control of the first process volume 402 and the second process volume 404, respectively.

Referring to FIG. 4, the process module 102 includes a first upper heater array 406 positioned above the first upper wall 430 of the first chamber body 308 and comprising a first lamp housing 408 in which a first plurality of lamps 414 are arranged. In addition, process module 102 includes a second upper heater array 410 positioned above the second upper wall 432 of the second chamber body 310 and comprising a second lamp housing 412 in which a second plurality of lamps 416 are arranged. In some embodiments, each one of the first plurality of lamps 414 and each one of the second plurality of lamps 416 can be positioned to extend laterally across and above the first upper walls 430 of the first chamber body 308 and second chamber body 310, respectively. In some embodiments, the first plurality of lamps 414 and the second plurality of lamps 416 are longitudinal spaced above the first upper walls 430 of the first chamber body 308 and the second chamber body 310 to enable uniform heating of the first substrate 118 and the second substrate 122 disposed within the first process volume 402 and second process volume 404, respectively. As used herein, the longitudinal axis of the chamber bodies (either 308 or 310) can refer to extensions/directions parallel, or substantially parallel, to the central plane 314, whereas the lateral axis of the chamber bodies can refer to extensions/directions perpendicular, or substantially perpendicular, to the central plane 314.

In another aspect, the process module 102 may comprise a first lower heater array 418 positioned below the first lower wall 434 of the first chamber body 308 and comprising a third lamp housing 420 in which a plurality of third lamps 426 are arranged. In another aspect, process module 102 may comprise a second lower heater array 422 positioned below the second lower wall 436 of the second chamber body 310 and comprising a fourth lamp housing 424 in which a plurality of fourth lamps 428 are arranged.

In some embodiments, each one of the plurality of third lamps 426 and each one of the plurality of fourth lamps 428 can be positioned to extend longitudinal across and above the first and second upper walls of the first chamber body 308 and second chamber body 310, respectively. In some embodiments, the plurality of third lamps 426 and the plurality of fourth lamps 428 are longitudinal spaced below the first and second lower walls of the first chamber body 308 and the second chamber body 310.

The various heater arrays described above (i.e., 406, 410, 418, and 422 of FIG. 4) can be independently controlled (e.g., via a controller, such as controller 244 of FIG. 2, for example) to enable, at least in part, autonomous temperature control of the first process volume 402 and the second process volume 404.

In another aspect independent temperature control between the first process volume 402 and the second process volume can be realized, at least in part, by utilizing a cooling system to provide a coolant fluid flow between the first chamber body 308 and the second chamber body 310 thereby at least partially providing temperature isolation between the first chamber body 308 and the second chamber body 310 and their associated interior process volumes.

In more detail and with reference to FIG. 3 and FIG. 4, the first chamber body 308 and the second chamber body 310 can be laterally separated by a longitudinal coolant channel 322. In some embodiments the longitudinal coolant channel 322 is defined, at least in part, by a channel formed by the separation between a portion of the first chamber exterior 324 proximate to the central plane 314 and a portion of the second chamber exterior 332 proximate to the central plane 314. In some embodiments the longitudinal coolant channel 322 is defined, at least in part, by a channel formed by the separation between external surfaces of the first and second chamber body that are proximate to the central plane 314. In certain examples the longitudinal coolant channel 322 can extend longitudinal between the front chamber flanges (336,338) and exhaust chamber flanges (340, 342) of the first chamber body 308 and the second chamber body 310. As a non-limiting example FIG. 3 illustrates the longitudinal coolant channel 322 extending longitudinally between the first injection chamber flanges 336 of the first and second chamber bodies 308/310 and the first exhaust chamber flanges 340 of the first and second chamber bodies 308/310.

In some embodiments, the longitudinal coolant channel 322 can be defined (or further defined) by one or more septum members which are configured to allow the coolant fluid flow across the one or more septum members to further independently control temperature of the first process volume 402 and the second process volume 404. In exemplary embodiments, and with further reference to FIG. 3 and FIG. 4, the process module 102 can further comprise a first longitudinal septum member 326 and a second longitudinal septum member 328. In such examples, the first longitudinal septum member 326 and the second longitudinal septum member 328 can extend longitudinally between the first and second injection chamber flanges (336, 338) and the first and second exhaust flanges (340, 342) of the first and second chamber bodies (308, 310).

In various embodiments, the longitudinal coolant channel and/or the longitudinal septum members can be coupled to a cooling system configured to provide a flow of coolant fluid into and through the longitudinal coolant channel. As a non-limiting example, the process module 102 (as illustrated in FIG. 3 and FIG. 4) can include the cooling system 344 which is configured to provide a flow of a coolant fluid (as indicated by coolant fluid flow 346) through the longitudinal coolant channel 322 and/or the first longitudinal septum member 326 and the second longitudinal septum member 328. In certain examples, the cooling system 344 can be positioned proximate to the exhaust chamber flanges (340, 342) and between of the first chamber body 308 and the second chamber body 310. In such examples, the cooling system 344 can be configured to direct the coolant fluid flow 346 longitudinally along the longitudinal coolant channel 322 in a flow direction towards the injection chamber flanges (336, 338) of the first chamber body 308 and the second chamber body 310. In various embodiments, the cooling system 344 may comprise a blower arrangement (or multi-blower arrangements) configured to provide a flow of temperature controlled (e.g., cooled) air longitudinally through the longitudinal coolant channel 322.

In various embodiments, the first chamber body and the second chamber body of the dual chamber process modules of the present disclosure comprise ceramic weldments including monolithic quartz assemblies configured to be housed in a common housing and each chamber body is further configured to couple to an injection flange and an exhaust flange.

For example FIG. 5 illustrates a cut-away sectional view through the B-B plane 306 of the process module 102 (as illustrated in FIG. 3) and illustrates the elements of the first chamber body 308 housed in the common chamber housing 312, as well as various assemblies and components of the process module 102 and there arrangement around the first chamber body, as described in detail below. Although the detailed description below is focused on the first chamber body, it should be appreciated that the following is equally as application to the second chamber body.

In various embodiments the process module 102 comprises a first chamber body 308 comprising a first upper wall 430 and a first lower wall 434. The first upper wall 430 extends longitudinally between a first injection chamber flange 336 (e.g., the injection end 352) and a longitudinally opposite first exhaust chamber flange 340 (e.g., the exhaust end 358). The first lower wall 434 is below and parallel relative to the first upper wall 430. The first chamber body has a plurality of first external ribs 330 extending laterally about a first chamber exterior of the first chamber body, the plurality of plurality of first external ribs 330 being longitudinally spaced part from one another between the first injection chamber flange 336 and the longitudinally opposite first exhaust chamber flange 340. In certain examples the plurality of external ribs comprise an upper wall rib portion and a lower rib portion, as described in greater detail below.

In various embodiments, the process module 102 (FIG. 5) comprises a first injection flange 354 configured to couple with the first injection chamber flange 336 of the first chamber body 308 and a first exhaust flange 360 configured to couple with first exhaust chamber flange 340 of the first chamber body 308.

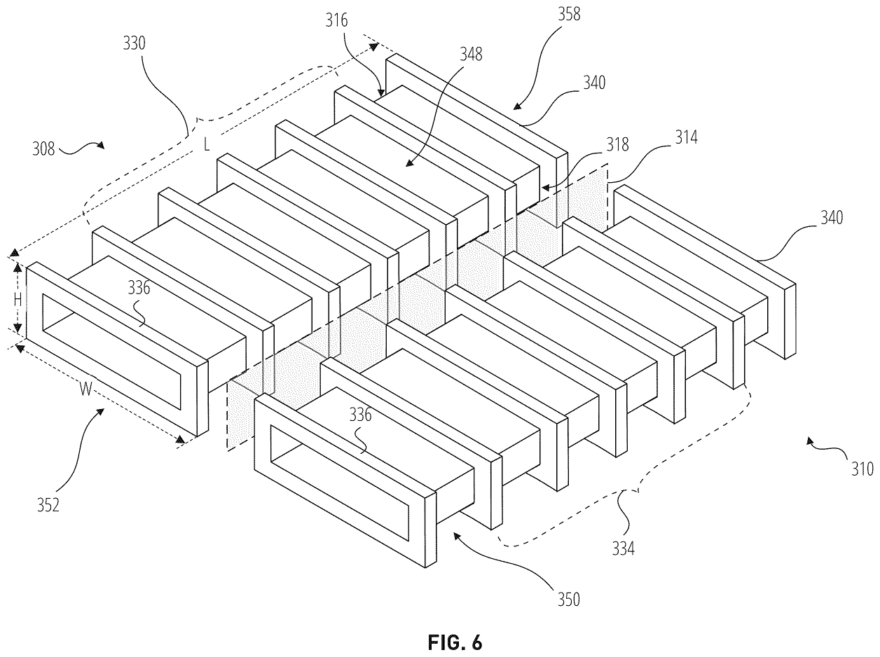

FIG. 6 illustrates a view of the first and second chamber bodies with all of the additional components and assemblies of the process module removed.

In various embodiments the chamber bodies (308 and/or 310) can have identical geometries. As used herein, the term “identical” is understood to include a percentage of variation in geometries due to imperfection in the manufacturing process employed to construct the chamber bodies. In such embodiments the longitudinal length of the chamber body (L) can be identical for the first chamber body 308 and the second chamber body 310. In addition, the lateral width (W) of the chamber body can be identical for the first chamber body 308 and the second chamber body 310. In addition, the height (H) of the chamber body can be identical for the first chamber body 308 and the second chamber body 310.

In certain examples, the first chamber body 308 and the second chamber body 310 have a length (L) to width (W) ratio between 1.0 and 0.2, between 0.8 and 0.3, between 0.7 and 0.4, or between 0.6 and 0.5. In certain examples, the first chamber body 308 and the second chamber body 310 have a length (L) to width (W) ratio of less than 1.0, less than 0.8, less than 0.7, less than 0.6, less than 0.5, less than 0.4, less than 0.3, or less than 0.2.

In other examples the process modules of the present disclosure may comprise chamber bodies (e.g., 308 and/or 310) having different geometries from each other.

In various embodiments, the first chamber body and the second chamber body of the process modules of the present disclosure may comprise ceramic weldments. In such examples, the first chamber body and second chamber body can include various structural components which are integrated into a one-piece unit. In certain examples, the ceramic weldments includes monolithic elements formed from a singular ceramic workpiece.

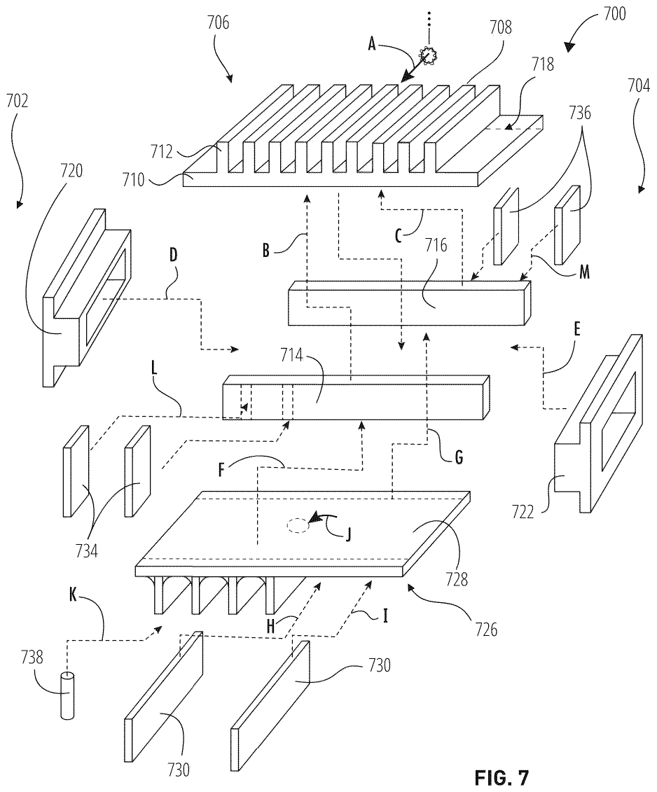

FIG. 7 illustrates the structural elements of an exemplary chamber body (e.g., either the first chamber body 308 or the second chamber body 310) comprising a ceramic weldment 700. As illustrated in FIG. 7 the ceramic weldment 700 is shown being assembled in an exploded form.

In various embodiments the ceramic weldment 700 includes an upper wall 706. The upper wall 706 comprises a singular ceramic workpiece 708 formed using a subtractive manufacturing technique. The upper wall 706 comprises an upper wall plate portion 710 and an upper wall rib portion 712, the upper wall plate portion 710 and the upper wall rib portion 712 having been defined by the removal of material from first monolithic ceramic workpiece.

As illustrated in FIG. 7, a first sidewall 714 is coupled to the upper wall 706 (as illustrated by arrow B). Likewise, a second sidewall 716 is coupled to the upper wall 706 (as illustrated by arrow C). In certain examples the first sidewall 714 and second sidewall 716 are coupled to an upper wall interior surface 718 at a location proximate to the longitudinal edges of the upper wall plate portion 710. The first sidewall 714 and the second sidewall 716 can be coupled to the upper wall 706 using welds.

In various embodiments the ceramic weldment 700 includes an injection chamber flange 720. The injection chamber flange 720 can be coupled to the upper wall 706 (as well as the first sidewall 714 and the second sidewall 716) as illustrated by arrow D. The injection chamber flange 720 can be coupled to the upper wall 706 (as well as the first sidewall 714 and the second sidewall 716) at the injection end 352 (as illustrated in FIG. 6).

In various embodiments the ceramic weldment 700 includes an exhaust chamber flange 722. The exhaust chamber flange 722 can be coupled to the upper wall 706 (as well as the first sidewall 714 and the second sidewall 716) as illustrated by arrow E. The exhaust chamber flange 722 can be coupled to the upper wall 706 (as well as the first sidewall 714 and the second sidewall 716) at the exhaust end 358 (as illustrated in FIG. 6).

In various embodiments the ceramic weldment 700 includes a lower wall 726. The lower wall may be coupled to one or more of the first sidewall 714, the second sidewall 716, the injection chamber flange 720 and the exhaust chamber flange 722 as illustrated by arrow F and arrow G. Advantageously, the aforementioned dimensional stability (e.g., resistance to deformation associated with localized heating) provided by the subtractive manufacturing technique employed to form the upper wall 706 may simplify formation of the weld coupling the lower wall 726, for example limiting (or eliminating) the need to remove native material to effect registration and/or fill gaps associated with dimensional changes.

In one aspect, the lower wall 726 comprises a singular ceramic workpiece formed using a subtractive manufacturing technique, as with upper wall 706. In such examples, the lower wall comprises a lower wall plate portion and a lower wall rib portion, the lower wall plate portion and the lower wall rib portion having been defined by the removal of material from a second monolithic ceramic workpiece.

In another aspect, the lower wall 726 comprises a non-singular ceramic workpiece and can include a lower wall plate 728 and a plurality of lower wall rib segments 730. In certain examples, the lower wall plate 728 can be coupled may be coupled to one or more of the first sidewall 714, the second sidewall 716, the injection chamber flange 720 and the exhaust chamber flange 722 as illustrated by arrow F and arrow G, and subsequently the plurality of lower wall rib segments 730 can be coupled to the lower surface of the lower wall plate 728, as indicated by arrow H and arrow I. The plurality of lower wall rib segments 730 may be sequentially registered to the lower wall plate 728. Registration may be accomplished at positions underlying the upper wall rib portion 712 of the upper wall 706, the upper wall rib portion 712 serving as a template to inform a fabricator as to where any one of the plurality of lower wall rib segments 730 should be positioned prior to welding.

As will be appreciated by those of skill in the art in view of the present disclosure, employment of the upper wall 706 as go/no-go gauge may further limit variation within the ceramic weldment 700 with respect to predetermined position of each of the lower wall rib segments 730 due to aforementioned lateral stiffness of the upper wall 706, also improving yield of the manufacturing process employed to fabricate the ceramic weldment 700.

In various embodiments, a passthrough 732 may be defined within the lower wall 726. In one aspect, a drilling operation can be employed at a location between two (2) longitudinally adjacent upper lower wall rib segments 730, as illustrated by arrow J. In another aspect the passthrough 732 may be defined within the lower wall 726 as part of a subtractive manufacturing process employed to form the lower wall 726.

As will be appreciated by those of skill in the art in view of the present disclosure, the subtractive manufacturing process employed to form the lower wall 726 may simplify either (or both) the forming of the passthrough 732 and the coupling of the tubulation body 738 due to stiffness imparted to the upper wall 706 by the unitary, one-piece construction of the upper wall 706 as well as the dimensional stability by absence of welds between at least the plurality of upper lower wall rib segments 730 and the upper wall plate portion 710 of the lower wall 726.

Various embodiments of the disclosure relate to the delivery of process gas to a process module including a first chamber body and a second chamber body. The complexity of the apparatus and systems employed for delivering independent process gas flows to a dual chamber process module having two chamber bodies can be significant and cost prohibitive. As such one or more embodiments provided apparatus for simplifying process gas delivery to a process module having two chamber bodies.

As a non-limiting example, a gas delivery system for a dual chamber process module can include individual flow controllers and gas delivery lines for all the process gas sources that are fed to the first chamber body and the second chamber body. In such examples the complexity and cost of the system increase exponentially while also making manufacture and repair of the system more complex. Therefore, the various embodiments provided employ shared flow controllers and shared gas delivery lines for certain gas sources thereby significantly reducing the semiconductor processing system complexity and cost.

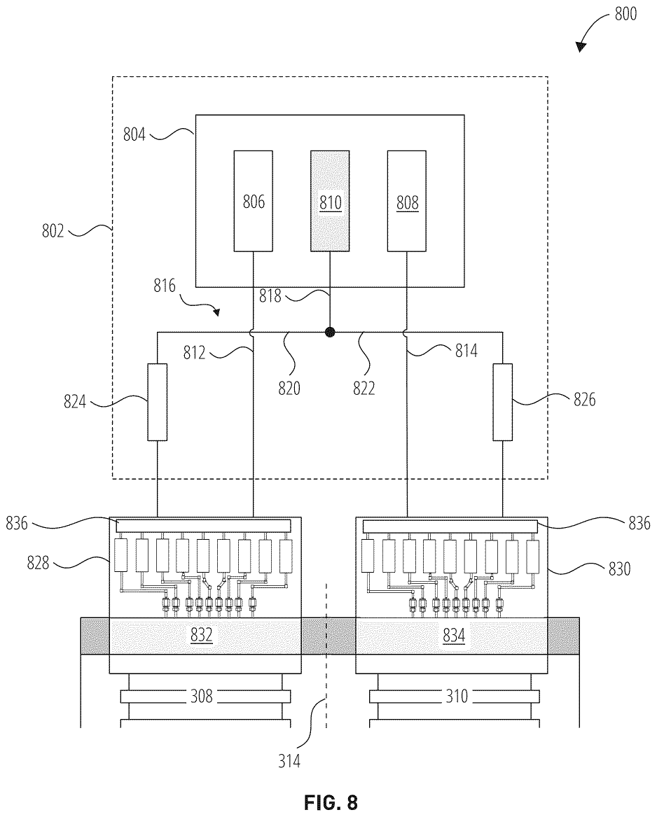

FIG. 8 illustrates a schematic of a portion of semiconductor processing system 800 according to one or more embodiments. Semiconductor processing system 800 comprises a gas delivery system 802 including a first source of a gas 806, a second source of the gas 808, and a source of an additional gas 810. As illustrated in FIG. 8, the first source of a gas 806 is fluidly coupled to the first chamber body 308 via a first gas distribution assembly 828 and the second source of the gas 808 is fluidly coupled to the second chamber body 310 via a second gas distribution assembly 830. In contrast, the source of an additional gas 810 is fluidly coupled to both the first chamber body 308 and the second chamber body 258 (via associated gas distribution assemblies) by employing a gas manifold 816. The gas manifold 816 receives the additional gas supplied from the source of an additional gas 810 (via input conduit 818) and distributes the additional gas to both the first chamber body 308 (via first output conduit 820) and the second chamber body 310 (via second output conduit 822). In such examples the sources of an additional gas 810 comprises common (e.g., shared) gas conduits to provide the additional gas to the first chamber body 308 and the second chamber body 310 thereby reducing the complexity of the gas delivery system.

In various embodiments, a first gas conduit 812 is fluidly coupled to the first source of a gas 806 and to the first chamber body 308 (via the first gas distribution assembly 828 and first injection flange assembly 832). A second gas conduit is fluidly coupled to the second source of the gas 808 and to the second chamber body 310 (via second gas distribution assembly 830 and second injection flange assembly 834). The gas manifold 816 includes an input conduit 818 for receiving the incoming additional gas supplied from the source of an additional gas 810. The gas manifold 816 includes a first output conduit 820 and a second output conduit 822 which redistribute the additional gas supplied from the source of an additional gas 810. The first output conduit 820 of the gas manifold 816 is fluid coupled to the input conduit 818 and the first chamber body (via first gas distribution assembly 828) and supplies the additional gas to the first chamber body 308. The second output conduit 822 of the gas manifold 816 is fluidly coupled to the input conduit 818 and the second chamber body 310 (via second gas distribution assembly 830) and supplies the additional gas to the second chamber body 310.

In various embodiments, a first flow controller 824 is coupled to the first output conduit 820 and is configured for controlling the flow of the additional to the first chamber body 308. A second flow controller is coupled to the second output conduit 822 and is configured for controlling the flow of the additional gas to the second chamber body 310.

As previous briefly stated above, the semiconductor processing system 800 comprises a first gas distribution assembly 828 and a second gas distribution assembly 830.

The first gas distribution assembly 828 and the second gas distribution assembly 830 can both include a plurality of gas lines (as illustrated in FIG. 8), each of the plurality of gas lines having an assocaited flow controller (not illustrated in FIG. 8). In certain examples the first gas distribution assembly 828 and the second gas distribution assembly 830 can include a manifold assembly 836. The manifold assembly 836 can be configured to redistribute the gas supplied from first source of a gas 806, second source of the gas 808, and the additional gas supplied from source of an additional gas 810 among the plurality of gas lines of the gas distribution assemblies (828/830).

The first gas distribution assembly 828 is fluidically coupled to the gas delivery system 802. In addition, the first gas distribution assembly 828 is fluidically coupled to the first chamber body 308 (via first injection flange assembly 832). In certain embodiments the first gas distribution assembly 828 is positioned within the semiconductor processing system 800 upstream of the first chamber body 308 and downstream of the gas delivery system 802.

The second gas distribution assembly 830 is fluidically coupled to the gas delivery system 802. In addition, the second gas distribution assembly 830 is fluidically coupled to the second chamber body 310 (via second injection flange assembly 834). In certain embodiments the second gas distribution assembly 830 is positioned within the semiconductor processing system 800 upstream of the second chamber body 310 and downstream of the gas delivery system 802.

As previously briefly stated above, the semiconductor processing system 800 comprises a first injection flange assembly 832 and a second injection flange assembly 834. The first injection flange assembly 832 is constructed and arranged to inject gas supplied from the first gas distribution assembly 828 into the interior of the first chamber body 308. The second injection flange assembly 834 is constructed and arranged to inject gas supplied from the second gas distribution assembly 830 into the interior of the second chamber body 310.

In various embodiments, the first injection flange assembly 832 is mechanically coupled to the first chamber body 308 and fluidically coupled to the first gas distribution assembly 828. Likewise, in various embodiments, the second injection flange assembly 834 is mechanically coupled to the second chamber body 310 and fluidically coupled to the second gas distribution assembly 830.

The first injection flange assembly 832 can include a plurality of internal flow channels (not illustrated), each one of the plurality of internal flow channels having an input being fluidly coupled to one of the plurality of gas lines of the first gas distribution assembly 828 and an output in fluid communication with the interior of the first chamber body 308 thereby enabling controlled distributed injection of a gas into the first process volume 402 (FIG. 4).

Likewise, the second injection flange assembly 834 can include a plurality of internal flow channels (not illustrated), each one of the plurality of internal flow channels having an input being fluidly coupled to one of the plurality of gas lines of the second gas distribution assembly 830 and an output in fluid communication with the interior of the second chamber body 310 thereby enabling controlled distributed injection of a gas into the second process volume 404 (FIG. 4).

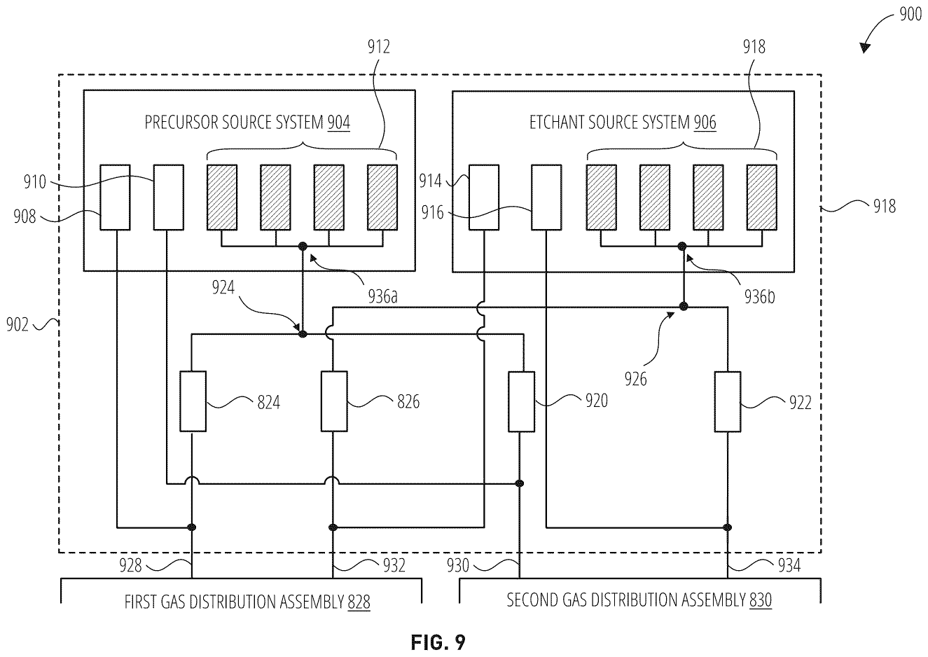

FIG. 9 illustrates a schematic of a portion of semiconductor processing system 900 according to one or more embodiments. Semiconductor processing system 900 is similar to semiconductor processing system 800 and elements common to both will be briefly described below.

The semiconductor processing system 900 includes a first gas distribution assembly 828 and a second gas distribution assembly 830 which are fluidly coupled to a first chamber body and a second chamber body respectively, as previously described for semiconductor processing system 800 of FIG. 8.

In various embodiments the gas delivery system 902 comprises a precursor source system 904 and an etchant source system 906. The precursor source system 904 comprises multiple gas sources including a first precursor source 908, a second precursor source 910, and a first additional source 912. The etchant source system 906 comprises multiple gas sources including a first etchant source 914, a second etchant source 916, and second additional source 918. In various embodiments the precursor source system 904 and/or the second additional source 918 can each supply both a gas in the form of a singular gas to first gas distribution assembly 828 and second gas distribution assembly 830 (and onto the associated first chamber body 308 and second chamber body) as well as a gas in form of a gas mixture (i.e., comprised of two or more different gases) to first gas distribution assembly 828 and second gas distribution assembly 830 (and onto the associated first chamber body 308 and second chamber body). The supply of a singular gas can be utilized when the epitaxial deposition processes being performed in the semiconductor processing system 900 are sensitive to variations in the flow of that particular gas. Correspondingly, the supply of a gas mixture can be utilized when the epitaxial deposition processes being performed in the semiconductor processing system 900 are less sensitive to variations in the flow of the gases making up the gas mixture.

In various embodiments, the first precursor source 908 and second precursor source 910 contain and supply a common chemical compound, i.e., the precursor gases supplied from first precursor source 908 and the second precursor source 910 are the same. In some embodiments the first precursor source 908 contains and supplies a single precursor gas (i.e., not a gas mixture) and the second precursor source 910 contains and supplies the same single precursor gas (i.e., not a mixture).

In various embodiments, the first etchant source 914 and second etchant source 916 contain and supply a common chemical etchant, i.e., the etchant gases supplied from first etchant source 914 and the second etchant source 916 are the same. In some embodiments the first etchant source 914 contains and supplies a single etchant gas (i.e., not a gas mixture) and the second etchant source 916 contains and supplies the same single etchant gas (i.e., not a mixture).

In various embodiments, the first additional source 912 of the precursor source system 904 and the second additional source 918 of the etchant source system 906 both comprise two or more gas sources as illustrated in FIG. 9.

In certain examples the two or more gas outputs of the first additional source 912 are coupled to the gas inputs of a mixing manifold 936a configured for mixing the incoming gases. The number of gas inputs to the mixing manifold 936a corresponds to the number of gas sources employed in the first additional source 912. As a non-limiting example, the first additional source 912 of FIG. 9 includes four (4) gas sources having four (4) gas outputs and the mixing manifolds 936a includes four (4) corresponding gas inputs for receiving and mixing gas supplied from each one of the four (4) gas sources of the first additional source 912. The mixing manifold 936a mixes incoming gases and includes a single gas output for suppling a first additional gas comprising a gas mixture to the downstream components of the gas delivery system 902.

Likewise, in certain examples the two or more gas outputs of the second additional source 918 are coupled to the gas inputs of a mixing manifold 936b configured for mixing the incoming gases. The number of gas inputs to the mixing manifold 936b corresponds to the number of gas sources employed in the second additional source 918. As a non-limiting example, the second additional source 918 of FIG. 9 includes four (4) gas sources having four (4) gas outputs and the mixing manifold 936b includes four (4) corresponding gas inputs for receiving and mixing gas supplied from each one of the four (4) gas sources of the second additional source 918. The mixing manifold 936b mixes incoming gases and includes a single gas output for suppling a second additional gas comprising a gas mixture to the downstream components of the gas delivery system 902.

Gas delivery system 902 comprises a first precursor input conduit 928 and a first etchant input conduit 932 fluidly connected to the first gas distribution assembly 828. The first precursor input conduit 928 is fluidly coupled to first precursor source 908 and the first additional source 912 via the first manifold 924 and the first flow controller 824. The first etchant input conduit 932 is fluidly coupled to first etchant source 914 and the second additional source 918 via the second manifold 926 and the second flow controller 826.

Gas delivery systems 902 comprises a second precursor input conduit 930 and a second etchant input conduit 934 fluidly connected to the second gas distribution assembly 830. The second precursor input conduit 930 is fluidly coupled to the second precursor source 910 and the first additional source 912 via the first manifold 924 and the third flow controller 920. The second etchant input conduit 934 is fluidly coupled to the second etchant source 916 and the second additional source 918 via the second manifold 926 and the fourth flow controller 922.

In some embodiments the first precursor source 908 and second precursor source 910 contain and supply a precursor gas having a chemical compound including an elemental component that is an elemental compound of the chemical formula of the epitaxially deposited material layer deposited in one or both of the chamber bodies. In certain examples, the precursor gas comprises silicon precursor or a germanium precursor.

In some embodiments the first etchant source 914 and the second etchant source 916 contain and supply an etchant gas having a chemical compound including an elemental component that is not an elemental compound of the chemical formula of the epitaxially deposited material layer deposited in one or both the chamber bodies. In certain examples, the etchant gas comprises a halide etchant (e.g., chlorine, hydrochloric acid, and the like).

In various embodiments the semiconductor processing systems provided can be configured for dual epitaxial deposition of material layers comprising compound materials having chemical formulae including two or more elemental components. As a non-limiting example, the semiconductor processing systems provided can be configured for dual epitaxial deposition of epitaxial silicon germanium layers including a silicon component and a germanium component.

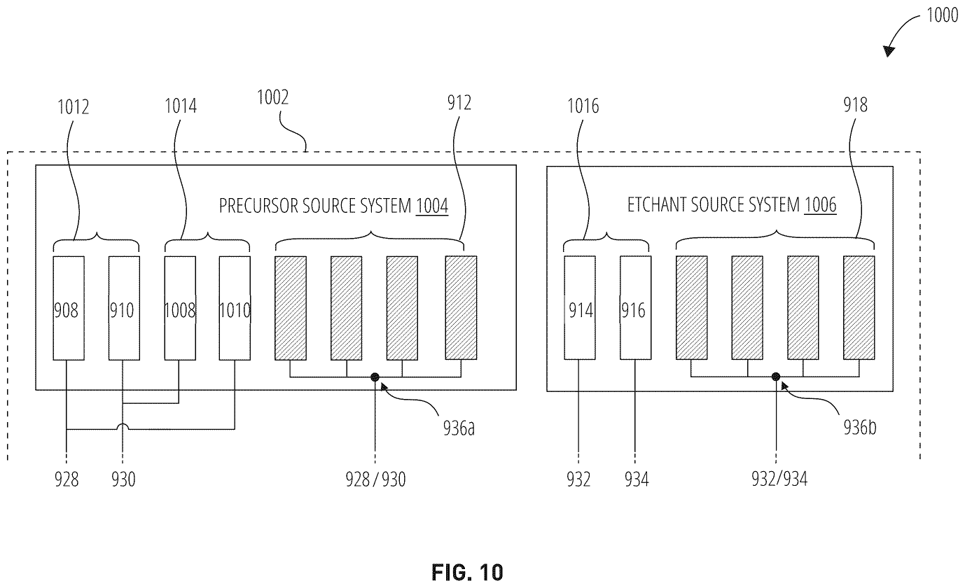

FIG. 10 illustrates a portion of a semiconductor processing system 1000 configured for dual epitaxial deposition of a compound material layer and in particular illustrates a portion of the gas delivery gas delivery system 1002 that can be employed in such a system.

In various embodiments the gas delivery system 1002 comprises a precursor source system 1004 and an etchant source system 1006. The first additional source 912, the second additional source 918, and the first etchant source 914/second etchant source 916 are similarly configured to that illustrated for gas delivery system 902 of FIG. 9.

In certain examples, the precursor source system 1004 comprises the first precursor source 908 and the second precursor source 910. The first precursor source 908 and second precursor source 910 can be configured to supply a first precursor gas 1012. In some embodiments the first precursor gas 1012 comprises a silicon precursor. In certain examples, the precursor source system 1004 comprises a third precursor source 1008 and a fourth precursor source 1010 configured to supply a second precursor gas 1014. In some embodiments the second precursor gas 1014 comprises a germanium precursor.

As a non-limiting example gas delivery system 1002 includes the first precursor source 908 and the second precursor source 910 configured to supply a silicon precursor to first precursor input conduit 928 and the second precursor input conduit 930 (see FIG. 9) and the third precursor source 1008 and the fourth precursor source 1010 configured to supply a germanium precursor to the first precursor input conduit 928 and the second precursor input conduit 930 thereby enabling the epitaxial deposition of silicon layers and/or silicon germanium layers in both the first chamber body 308 and the second chamber body (FIG. 9). In certain examples the semiconductor processing system 1000 including the gas delivery system 1002 can be configured for dual epitaxial deposition of silicon germanium/silicon superlattice structures comprising multiple repeated layers of epitaxial silicon and epitaxial silicon germanium. In such examples the etchant gas 1016 (supplied from first etchant source 914 and second etchant source 916) may comprise a halide etchant (e.g., hydrochloric acid gas).

In additional examples, the first precursor source 908 and second precursor source 910 can be configured to supply a first precursor gas 1012. In such examples the first precursor gas 1012 can comprise a silicon precursor. In addition, the third precursor source 1008 and a fourth precursor source 1010 can be configured to supply a second precursor gas 1014 comprising a dopant gas. For example, the first precursor source 908 and second precursor source 910 can supply a silicon precursor and the third precursor source 1008 and the fourth precursor source 1010 can supply a p-type or a n-type dopant thereby enabling the epitaxial deposition doped silicon layers in both the first chamber body 308 and the second chamber body 310. In such examples the semiconductor processing system 1000 including the gas delivery system 1002 can be configured for dual epitaxial deposition of PMOS or NMOS epitaxial layers comprising doped epitaxial silicon layers. In such examples the etchant gas 1016 (supplied from first etchant source 914 and 916 can comprise a halide etchant (e.g., hydrochloric acid gas).

The various embodiments provided also include exhaust assemblies configured for independently controlling the pressure and rate of exhaust of excess precursor and reaction byproducts from a process module including a first chamber and a second chamber. In brief, the exhaust assemblies provided have a reduced complexity whilst still enabling independent operable exhaust control of the first and second chambers.

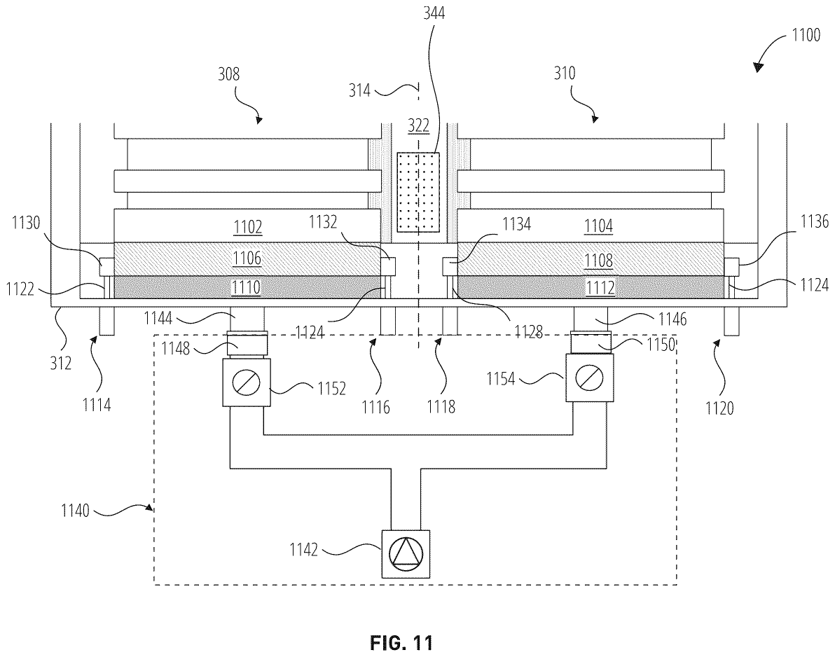

The exhaust assemblies and their component elements are illustrated with reference to FIGS. 11-15. Elements previously described above are described in brief while additional elements are described in greater detail. As used herein with reference to surfaces “inner” can refer to a surface facing towards a chamber body and likewise “outer” can refer to a surface facing away from a chamber body.

In various embodiments, a process module 1100 (FIG. 11) comprises a common chamber housing 312, and a first chamber body 308 and a second chamber body 310. The chamber bodies are disposed within the common chamber housing 312 and are laterally separated by a lateral separation distance and are positioned adjacent to one another on either side of a central plane 314. In such examples, the first chamber body 308 comprising a first ceramic weldment having a first upper wall and a first lower wall, the first upper wall extending longitudinally between a first injection chamber flange and a longitudinally opposite first exhaust chamber flange, the first lower wall being below and parallel relative to the first upper wall, as described previously. In such examples, a second chamber body 310 is disposed in the common chamber housing, the second chamber body comprising a second ceramic weldment a second upper wall and a second lower wall, the second upper wall extending longitudinally between a second injection chamber flange and a longitudinally opposite second exhaust chamber flange, the second lower wall being below and parallel relative to the second upper wall, as previously described.

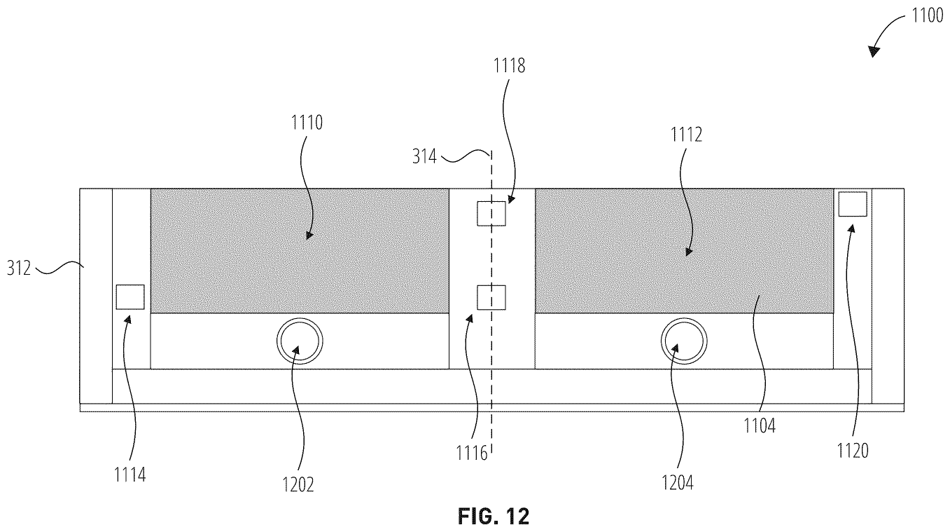

In various embodiments and with reference to FIG. 11 and FIG. 12, the first chamber body 308 includes the first exhaust chamber flange 1102 and the second chamber body 310 includes the second exhaust chamber flange 1104, the first exhaust chamber flange 1102 and the second exhaust chamber flange 1104 being integral to the first chamber body 308 and the second chamber body 310 respectively. A first exhaust flange 1106 is coupled to the first exhaust flange 1106 and a second exhaust flange 1108 is coupled to the second exhaust chamber flange 1104. The first and second exhaust flanges can be formed of any suitable material, such as stainless steel or Hastelloy. A first cover plate 1110 is coupled to the first exhaust flange 1106 and a second cover plate 1112 is coupled to the second exhaust flange 1108.

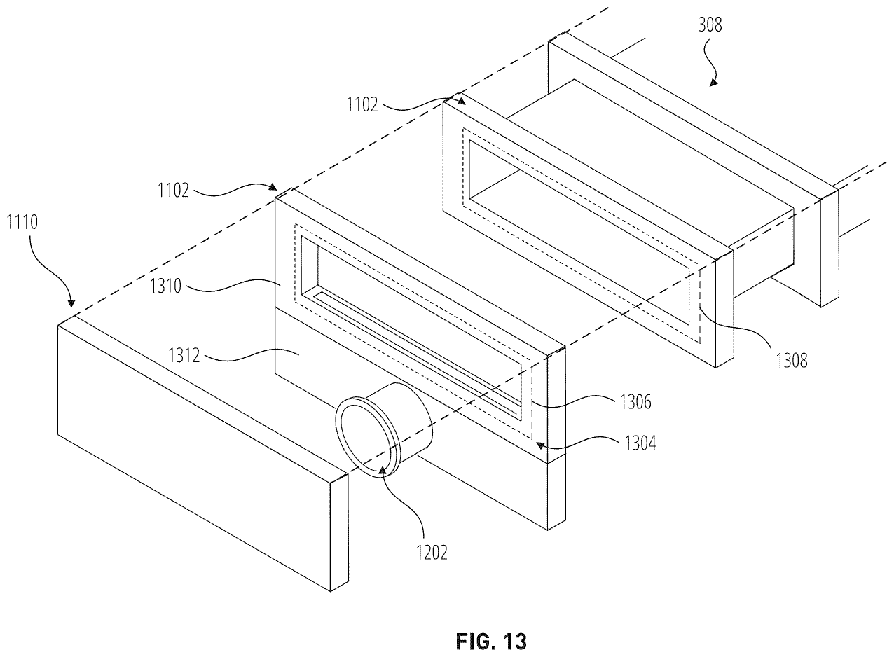

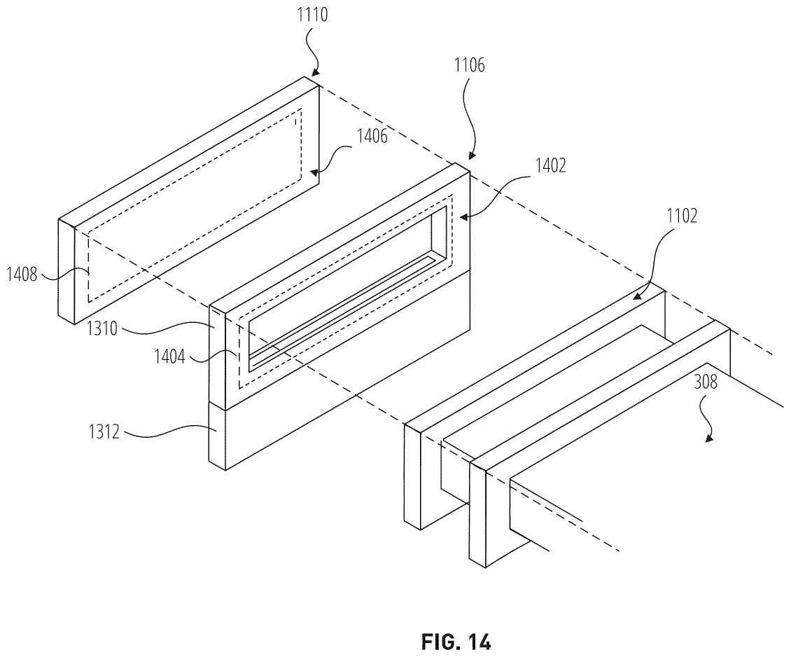

FIG. 13 and FIG. 14 illustrate the first and second exhaust flanges (1106, 1108) and the first and second cover plates (1110, 1112) and how they are assembled in greater detail. For example, FIG. 13 illustrates an exploded view of elements of the exhaust assembly as observed looking toward the first exhaust chamber flange 1102 of the first chamber body 308, whereas FIG. 14 illustrates an exploded view of elements of the exhaust assembly as observed looing away from the first exhaust chamber flange 1102 of the first chamber body 308. In various embodiment the first chamber body, exhaust flange, cover plate, and the like, are structural the same or substantially similar and assembly in the same or substantially similar manner to the second chamber body, exhaust flange, cover plate, and the like, and therefore the following description of the first exhaust assembly similarly applies to the second exhaust assembly.

In various embodiments and with reference to FIG. 13 and FIG. 14, the first exhaust flange 1106 comprises a first inner sealing surface 1402 configured to form a seal (e.g., a vacuum seal) with the first exhaust chamber flange 1102. To form a seal between the first exhaust flange 1106 and the first inner sealing surface 1402, the first inner sealing surface 1402 includes an inner recess 1404 constructed and arranged to receive a sealing member (e.g., an O-ring or the like) and the first exhaust chamber flange 1102 includes a first chamber recess 1308 constructed and arranged to receive the sealing member. The first cover plate 1110 comprises a first plate sealing surface 1406 configured to form a seal with the first outer sealing surface 1304 of the first exhaust flange 1106. To form a seal between the first cover plate 1110 and the first inner sealing surface 1402, the first plate sealing surface 1406 comprises the first cover recess 1408 constructured and arranged to receive a sealing member and the first outer sealing surface 1304 comprises an outer recess 1306 constructured and arranged to receive the sealing member.

In various embodiments, the coupling of, and the formation of the seal (i.e., a vacuum seal) between the first exhaust chamber flange 1102 and the first exhaust flange 1106, and between second exhaust chamber flange 1104 and second exhaust flange 1108 is achieved by employing a series of pressure cylinders.

In some embodiments, to maintain the necessary compressive forces between the first exhaust flange 1106 and the first chamber body 308, the process module 1100 is equipped with a first pressure cylinder 1114 and a second pressure cylinder 1116. These cylinders are connected to the common chamber housing 312 and include a first piston 1122 and a second piston 1124, respectively. These pistons are coupled to the first exhaust flange 1106 and are configured to apply a compressive force between the first exhaust flange 1106 and the first exhaust chamber flange 1102, thereby maintaining a seal (and an internal vacuum) within the first chamber body 308.

Likewise, to maintain the necessary compressive forces between the second exhaust flange 1108 and the second chamber body 310, the process module 1100 is equipped with a third pressure cylinder 1118 and a fourth pressure cylinder 1120. These cylinders are connected to the common chamber housing and include a third piston 1126 and a fourth piston 1128, respectively. These pistons are coupled to the second exhaust flange 1108 and are configured to apply a compressive force between the second exhaust flange 1108 and the second injection first exhaust chamber flange 1102, thereby maintaining a seal (and an internal vacuum) within the second chamber body 310.

In various embodiments the first and second exhaust flanges comprise a flange member 1310 and an exhaust port member 1312.

In various embodiments, the first pressure cylinder 1114 is attached to a first side of the first exhaust flange at a first vertical position and the second pressure cylinder is attached to a second side of the first exhaust flange at a second vertical position different from the first vertical position. Likewise, the third pressure cylinder is attached to a first side of the second exhaust flange at a first vertical position and the fourth pressure cylinder is attached to a second side of the second exhaust flange at a second vertical position different from the first vertical position.

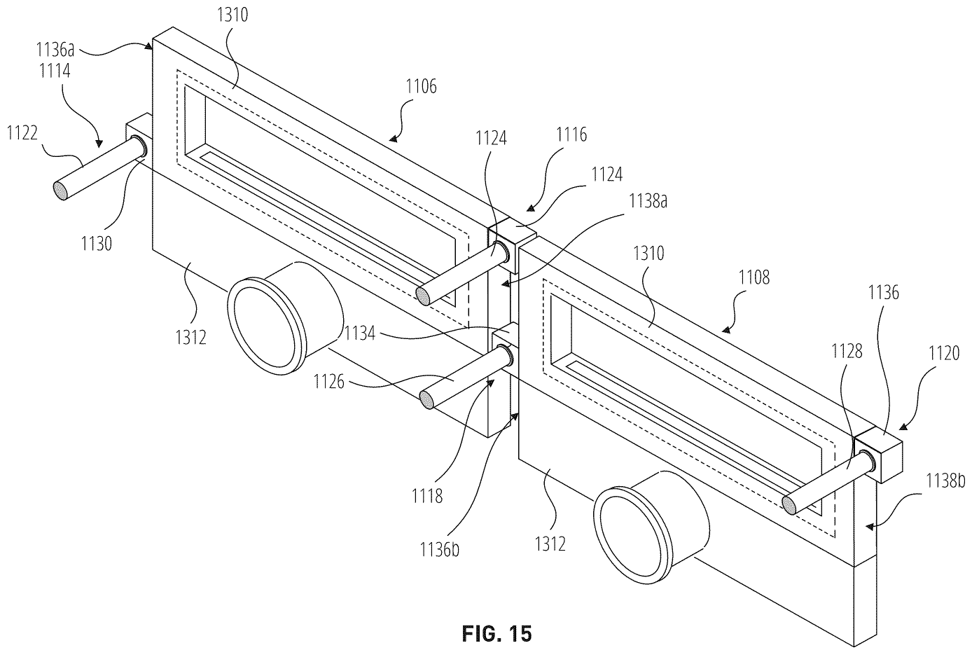

As a non-limiting examples, FIG. 15 illustrates the first and second exhaust flanges (1106, 1108) with their associated pressure cylinders in position. Note the housings of the pressure cylinders are omitted. As illustrated in FIG. 15, the first pressure cylinder 1114 is attached to a first side 1136a of the first exhaust flange 1106 via a first coupling 1130 and the second pressure cylinder 1116 is attached to a second side 1138a of the first exhaust flange 1106 via a second coupling 1132. Likewise, the third pressure cylinder 1118 is attached to a first side 1136b of the second exhaust flange 1108 via a third first coupling 1130 and the third pressure cylinder 1118 is attached to a second side 1138b of the second exhaust flange 1108 via a fourth coupling 1136.

In certain embodiments the first coupling 1130 is position proximate to the base of the flange member 1310 of the first exhaust flange 1106 and the second coupling is positioned proximate to the top of the flange member 1310 of the first exhaust flange, as illustrated in FIG. 15. Likewise, the third coupling 1134 can be positioned proximate to the base of the flange member 1310 of the second exhaust flange 1108 and the fourth coupling 1136 can be positioned proximate to the top of the flange member 1310 of the second exhaust flange 1108. In other embodiments, the positions of the couplings can be mirrored such that the first coupling 1130 and the third coupling 1134 are positioned at the top the of the flange members 1310, and the second coupling 1132 and the fourth coupling 1136 are positioned at the base the flange members 1310.

The positioning of the pressure cylinders and their associated couplings at the positioned described above can have the advantage of a facilitating a compact form for the exhaust assembly and correspondingly the process module 1100. For example, as illustrated in FIG. 12, the second pressure cylinder 1116 and the third pressure cylinder 1118 can be positioned vertically over one another, thereby reducing the real estate required to house the pressure cylinders.

In various embodiments, a vacuum assembly is coupled to the exhaust assembly of the process module, i.e., to the first exhaust port and the second exhaust port. For example, the vacuum assembly can be configured to provide independent control of an exhaust pressure from each of the first chamber body and the second chamber body.

The vacuum assembly is designed to efficiently manage the removal of gases and maintain the desired pressure levels within the chamber bodies.

Referring back to FIG. 11, the vacuum assembly 1140 can comprise a common vacuum source 1142, which can serve as the primary mechanism for creating the vacuum conditions within the first chamber body 308 and the second chamber body 310. The common vacuum source 1142 is connected to both the first and second chamber bodies through dedicated exhaust conduits.

In various embodiments, a first exhaust conduit 1148 is coupled to the first exhaust port 1144 of the first chamber body 308 and extends to the common vacuum source 1142. The first exhaust conduit 1148 facilitates the removal of gases from the first chamber body, ensuring that the internal environment remains stable and conducive for the epitaxial deposition process. To regulate the pressure within the first chamber body 308, a first pressure control valve 1152 is operably coupled to the first exhaust conduit 1148. The first pressure control valve 1152 allows for precise control of the pressure levels, ensuring that the desired vacuum conditions are maintained within the first chamber body. Similarly, the second exhaust conduit 1150 is coupled to the second exhaust port 1146 of the second chamber body 310 and extends to the common vacuum source 1142. The second exhaust conduit 1150 performs the same function as the first exhaust conduit, but for the second chamber body. The second exhaust conduit 1150 ensures the efficient removal of gases and maintains the stability of the internal environment. A second pressure control valve 1154 is operably coupled to the second exhaust conduit 1150, providing the same level of precise pressure control as the first valve. This ensures that the vacuum conditions within the second chamber body are also maintained at the desired levels.

The integration of these components within the vacuum assembly (1140) allows for the concurrent independent management of gases and pressure levels in both chamber bodies. The common vacuum source 1142, in conjunction with the first and second exhaust conduits and their respective pressure control valves, ensures that the process module (1100) operates efficiently and effectively, supporting the concurrent epitaxial deposition of material layers.

In various embodiments the process modules provided include independently controllable lift mechanisms for raising and lowering the upper lamp housings containing the plurality of heating lamps employed to heat the interiors of the first chamber body and the second chamber body. By independently controlling the upper lamp housings, the plurality of lamps can be more readily access when maintenance and/or replacement of the lamps is needed.

In one or more embodiments of the disclosure, the process module includes a support framework comprising a vertical framework and a horizontal framework, a common chamber housing supported by the support framework, and first and second chamber bodies disposed in the common chamber housing. Each chamber body comprises a ceramic weldment with an upper wall and a lower wall. The module also includes first and second lamp housings for heating the interiors of the chamber bodies, and first and second lift mechanisms for independently raising and lowering the lamp housings.

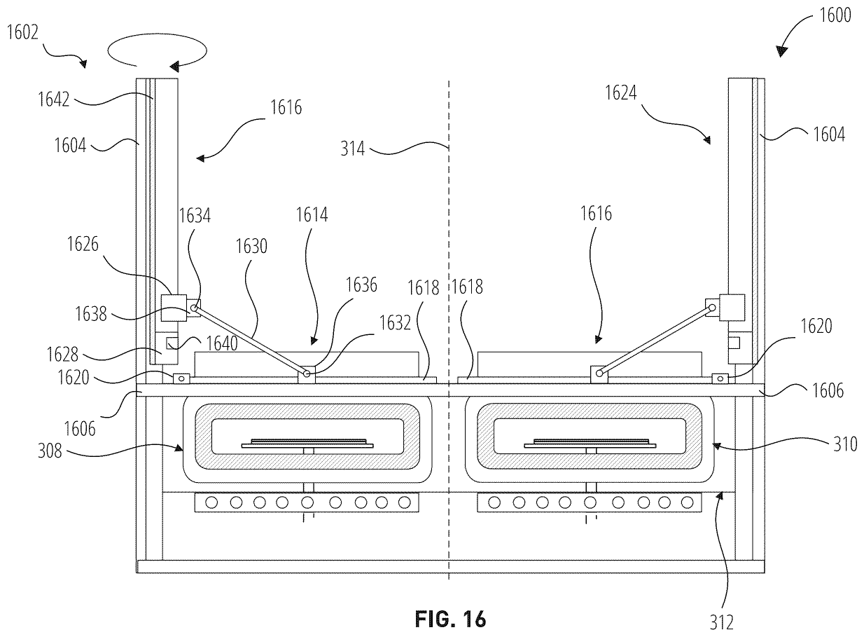

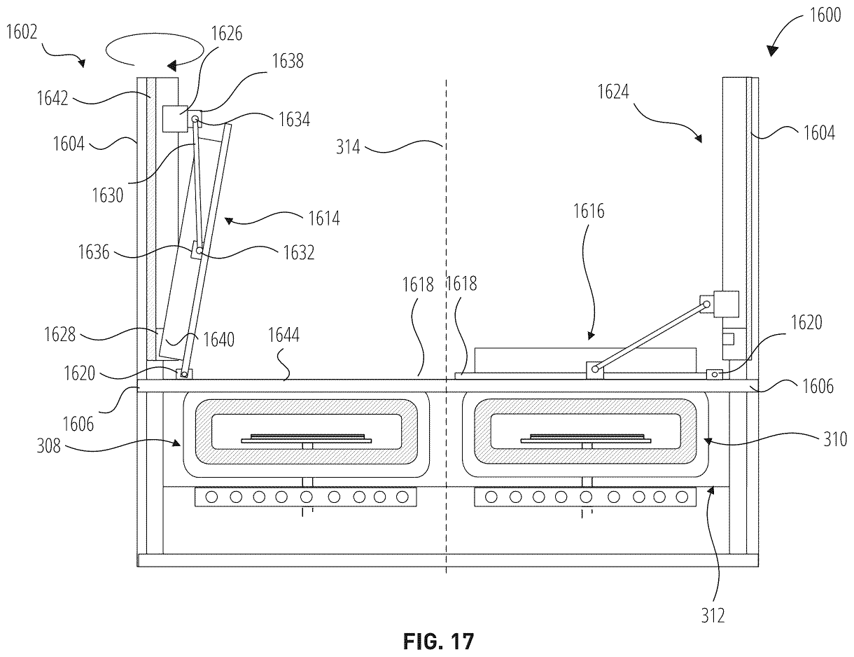

FIG. 16 and FIG. 17 illustrate one or more embodiments of the lift mechanisms. FIG. 16 illustrates a schematic view of a process module 1600 with both the lamp housings in the closed position whereas FIG. 17 illustrates a schematic view of the process module 1600 with the first lamp housing the open position and the second lamp housing the closed position.

In various embodiments the process module 1600 comprises a support framework 1602 that includes a vertical framework 1604 and a horizontal framework 1606. The vertical framework 1604 can provide structural support, while the horizontal framework 1606 can offer stability and alignment for the components housed within the process module.

A common chamber housing 312 is supported by the support framework 1602. This housing encloses the first chamber body 308 and the second chamber body 310, which are positioned adjacent to one another on either side of a central plane 314. Each chamber body comprises a ceramic weldment with an upper wall and a lower wall. The upper wall extends longitudinally between an injection chamber flange and a longitudinally opposite exhaust chamber flange, while the lower wall is positioned below and parallel to the upper wall, moveable lifting elements previously described.

The first lamp housing 1614 and the second lamp housing 1616 are configured for heating the interiors of the first chamber body 308 and the second chamber body 310, respectively. The first lamp housing 1614 and the second lamp housing 1616 are positioned on either side of the central plane 314 and each comprises a housing base 1618 that is hingedly connected to the horizontal framework 1606 by a hinged mechanism 1620. A first lift coupling 1636 is positioned on the upper surface of the housing base 1618.

The first lift mechanism 1622 and the second lift mechanism 1624 are operably connected to the vertical framework 1604. Each lift mechanism includes a moveable lifting element 1626 with a second lift coupling 1638, a drive mechanism 1628 configured to raise and lower the moveable lifting element 1626 about the vertical framework 1604, and a lifting arm 1630 with a first pivoting end 1632 connected to the first lift coupling 1636 and a second pivoting end 1634 connected to the second lift coupling 1638. These lift mechanisms are designed to independently raise and lower the first lamp housing 1614 and the second lamp housing 1616 between a closed position and an open position.

The support framework 1602 is constructed from durable materials to ensure stability and longevity. The vertical framework 1604 is designed to withstand the weight and operational stresses of the common chamber housing 312 and the lamp housings (1614, 1616). The horizontal framework 1606 provides additional support and alignment, ensuring that the chamber bodies and lamp housings remain properly positioned during operation.

In various embodiments, the first lift mechanism 1622 and the second lift mechanism 1624 further comprise a position sensor 1640 configured to monitor the position of the first lamp housing and the second lamp housing during raising and lowering operations. This position sensor 1640 ensures accurate and precise control of the lamp housings, enhancing the overall performance of the process module.

In various embodiments, the drive mechanism 1628 comprises a smart motor configured to control and regulate the travel speed of the first lamp housing 1614 and the second lamp housing 1616 during raising and lowering operations. The smart motor is operably linked to the position sensor 1640 and is configured to reduce the travel speed of the first lamp housing 1614 and the second lamp housing 1616 when proximate to the first chamber body 308 and the second chamber body 310 during lowering operations. These features can prevent the movement of the lamp housings during raising and lowering operations from shifting elements (e.g., the support substrate) within the chamber bodies and also prevent any sudden movements that could disrupt the deposition process.

Additionally, the smart motor can further be configured to reduce the travel speed of the first lamp housing 1614 and the second lamp housing 1616 when proximate to the vertical framework 1604 during raising operations. This ensures smooth and controlled movement of the lamp housings, reducing the risk of mechanical failure or misalignment.

In various embodiments, the first lift mechanism 1622 and the second lift mechanism 1624 are connected to the vertical framework 1604 by a pivot mechanism 1642. This pivot mechanism 1642 is configured to allow rotation of the first lamp housing 1614 and the second lamp housing 1616 about the vertical framework 1604 when in the open position. The pivot mechanism 1642 rotates the first lamp housing 1614 and the second lamp housing 1616 about the vertical framework 1604 toward the exhaust chamber flanges (see FIG. 7), thereby enabling access to a first plurality of lamps disposed in the first lamp housing 1614 and a second plurality of lamps disposed in the second lamp housing 1616.

FIG. 17 illustrates the process module 1600 with the first lamp housing 1614 in the open position and the second lamp housing 1616 in the closed position. The raising of the first lamp housing 1614 to the open position can be achieve by engaging the drive mechanism 1628 thereby vertically raising the moveable lifting element 1626 relative to the vertical framework.

In various embodiments, the horizontal framework 1606 further comprises an operable slide mechanism 1644 configured to allow the first lamp housing and the second lamp housing to be moved in a direction away from the exhaust flanges when in the open position. This feature facilitates maintenance and replacement of the lamps, enhancing the overall serviceability of the process module.

In additional embodiments, the first lift mechanism 1622 is configured to operably move the first plurality of lamps (e.g., 414 of FIG. 4) between the closed position, where the first plurality of lamps are positioned above the upper wall (e.g., 430 of FIG. 4) of the first chamber body, and an open position, where the first plurality of lamps (e.g., 414 of FIG. 4) are proximate to the vertical framework 1604. Similarly, the second lift mechanism 1624 is configured to operably move the second plurality of lamps (e.g., 416 of FIG. 4) between the closed position, where the second plurality of lamps are positioned above the upper wall (e.g., 430 of FIG. 4) of the second chamber body, and an open position, where the second plurality of lamps are proximate to the vertical framework 1604.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing system configured for performing concurrent epitaxial deposition of material layers in a process module comprising a first chamber body and a second chamber body, the semiconductor processing system comprising:
a gas delivery system comprising a first source of a gas, a second source of the gas, and a source of an additional gas;
a first gas conduit fluidly coupled to the first source of a gas and to the first chamber body,
a second gas conduit fluidly coupled to the second source of the gas and to the second chamber body; and
a gas manifold comprising an input conduit coupled to the source of the additional gas, a first output conduit fluidly coupled to the input conduit and the first chamber body, and a second output conduit fluidly coupled to the input conduit and the second chamber body;
a first flow controller operably coupled to the first output conduit and configured for controlling the flow of the additional gas to the first chamber body; and
a second flow controller operably coupled to the second output conduit and configured for controlling the flow of the additional gas to the second chamber body,
wherein the first chamber body and the second chamber body both have an upper wall and a lower wall, the upper wall extending longitudinally between an injection chamber flange and a longitudinally opposite exhaust chamber flange, the lower wall being below and parallel relative to the upper wall, and
wherein the first chamber body and the second chamber body are laterally separated by a lateral separation distance and positioned adjacent to one another on either side of a central plane.

2. The semiconductor processing system of claim 1, further comprising a first gas distribution assembly fluidically coupled downstream to gas delivery system and fluidically coupled upstream to the first chamber body, and a second gas distribution assembly fluidically coupled downstream to the gas delivery system and fluidically coupled upstream to the second chamber body.

3. The semiconductor processing system of claim 2, further comprising a first injection flange assembly mechanically coupled to the first chamber body and fluidically coupled to the first gas distribution assembly, and a second injection flange assembly mechanically coupled to the second chamber body and fluidically coupled to the second gas distribution assembly.

4. The semiconductor processing system of claim 2, wherein the gas delivery system further comprises a precursor source system including one or more precursor gases and an etchant source system including one or more etchant gases.

5. The semiconductor processing system of claim 4, wherein the first gas distribution assembly and the second gas distribution assembly both comprise:
a plurality of precursor gas lines fluidly coupled to the precursor source system; and
a plurality of etchant gas lines fluidly coupled to the etchant source system.

6. The semiconductor processing system of claim 5, wherein the first source of the gas and the second source of the gas comprise a precursor gas, the precursor gas comprising a chemical compound including an elemental component that is an elemental component of the chemical formula of the epitaxially deposited material layer.

7. The semiconductor processing system of claim 6, wherein the precursor gas comprises at least one of a silicon precursor, a germanium precursor, and a dopant gas.

8. The semiconductor processing system of claim 5, wherein the additional gas comprises an etchant gas or an inert gas comprising a chemical compound including an elemental component that is not an elemental component of the chemical formula of the epitaxially deposited material layer.

9. The semiconductor processing system of claim 8, wherein the additional gas is an inert gas.

10. The semiconductor processing system of claim 5, wherein the first source of the gas and the second source of the gas comprise an etchant gas, the etchant gas comprising a chemical compound including an elemental component that is not an elemental component of the chemical formula of the epitaxially deposited material layer.

11. The semiconductor processing system of claim 10, wherein the etchant gas comprises a halide etchant.

12. The semiconductor processing system of claim 1, wherein the first chamber body comprises a first ceramic weldment having a first chamber exterior comprising a plurality of first external ribs extending laterally about the first chamber exterior, and a first chamber interior enclosing a first process volume and wherein the second chamber body comprising a second ceramic weldment having a second chamber exterior comprising a plurality of second external ribs extending laterally about the second chamber exterior, and a second chamber interior enclosing a second process volume.

13. The semiconductor processing system of claim 12, wherein the upper wall comprises an upper wall plate portion and an upper wall rib portion defining an upper wall unwelded ribbed region formed from a first singular quartz workpiece using a subtractive manufacturing technique thereby forming an upper portion of the plurality of first external ribs and the plurality of second external ribs.

14. The semiconductor processing system of claim 13, wherein the lower wall comprising a lower wall plate portion and a lower wall rib portion defining a lower wall unwelded ribbed region formed from a second singular quartz workpiece using a subtractive manufacturing technique and forming a lower portion of the plurality of first external ribs and the plurality of second external ribs.

15. The semiconductor processing system of claim 14, further comprising a longitudinal coolant channel disposed between the first chamber body and the second chamber body, the longitudinal coolant channel being defined at least in part by the lateral separation distance between the first chamber body and the second chamber body.

16. The semiconductor processing system of claim 15, further comprising a cooling system coupled to the longitudinal coolant channel, the cooling system configured to provide a coolant fluid flow through the longitudinal coolant channel thereby at least partially providing temperature isolation between the first process volume and the second process volume.

17. The semiconductor processing system of claim 16, wherein the longitudinal coolant channel further comprises a first longitudinal septum member coupled to the first chamber body and a second longitudinal septum member coupled to the second chamber body;
wherein the first longitudinal septum member and the second longitudinal septum member are laterally positioned adjacent to one another on either side of the central plane; and
wherein the first longitudinal septum member and the second longitudinal septum member form a heat exchanger assembly configured to receive the coolant fluid flow from the cooling system.

18. The semiconductor processing system of claim 15, wherein the semiconductor processing system comprises a cluster-type platform comprising one or more process modules.

19. A semiconductor processing system configured for performing concurrent epitaxial deposition of material layers in a process module comprising a first chamber body and a second chamber body, the semiconductor processing system comprising:
a gas delivery system comprising a first source of a gas and a source of an additional gas;
a first gas conduit fluidly coupled to the first source of a gas and to the first chamber body; and
a gas manifold comprising an input conduit coupled to the source of the additional gas, a first output conduit fluidly coupled to the input conduit and the first chamber body, and a second output conduit fluidly coupled to the input conduit and the second chamber body;
wherein the source of the additional gas comprises two or more gas sources and a mixing manifold;
wherein the two or more gas sources of the source of the additional gas are coupled to gas inputs of the mixing manifold;
wherein the mixing manifold is configured for mixing incoming gases and includes a single gas output coupled to the input conduit; and
wherein the first source of a gas is configured to contain and supply a single gas.

20. A semiconductor processing system configured for performing concurrent epitaxial deposition of material layers in a process module comprising a first chamber body and a second chamber body, the semiconductor processing system comprising:
a gas delivery system comprising a precursor source system including a first precursor source and a first additional source, and an etchant source system including a first etchant source and a second additional source ;
a precursor input conduit fluidly coupled to the first precursor source and to the first chamber body;
an etchant input conduit fluidly coupled to the first etchant source and to the first chamber body; and
a first manifold coupling the first additional source to the first chamber body and to the second chamber body;
a second manifold coupling the second additional source to the first chamber body and to the second chamber body; wherein the first additional source comprises two or more precursor gas sources and a first mixing manifold;
wherein the two or more precursor gas sources of the first additional source are coupled to gas inputs of the first mixing manifold;
wherein the first mixing manifold is configured for mixing incoming gases and includes a single gas output coupled to the first manifold;
wherein the first precursor source is configured to contain and supply a single gas,
wherein the second additional source comprises two or more etchant gas sources and a second mixing manifold;
wherein the two or more etchant gas sources of the second additional source are coupled to gas inputs of the second mixing manifold;
wherein the second mixing manifold is configured for mixing incoming gases and includes a single gas output coupled to the second manifold; and
wherein the first etchant source is configured to contain and supply a single gas.
